(19) United States
(12) Patent Application Publication
(10) Pub. No.: US 2025/0393360 A1
(43) Pub. Date: Dec. 25, 2025

(54) DISPLAY DEVICE AND METHOD FOR MANUFACTURING THE SAME

(71) Applicant: Samsung Display Co., LTD., Yongin-si (KR)

(72) Inventors: Kyung Rock SON, Yongin-si (KR); Jae Phil LEE, Yongin-si (KR); Won Ho JANG, Yongin-si (KR)

(21) Appl. No.: 19/019,136

(22) Filed: Jan. 13, 2025

(30) Foreign Application Priority Data
Jun. 21, 2024 (KR) 10-2024-0080716

(51) Int. Cl. H10H 29/49; H10H 29/01

(52) U.S. Cl. CPC H10H 29/49; H10H 29/012

(57) ABSTRACT

A display device includes a substrate, a pixel electrode and a common electrode above the substrate, a first reflective electrode and a second reflective electrode respectively above the pixel electrode and the common electrode, a first sacrificial electrode and a second sacrificial electrode respectively above the first reflective electrode and the second reflective electrode, an organic layer above the first sacrificial electrode and the second sacrificial electrode, a light-emitting element above the organic layer, and including a semiconductor stack, a first contact electrode, and a second contact electrode, a first connection electrode connecting the pixel electrode and the first contact electrode through a first connection hole in the organic layer and the first sacrificial electrode, and a second connection electrode connecting the common electrode and the second contact electrode through a second connection hole in the organic layer and the second sacrificial electrode.

### CROSS-REFERENCE TO RELATED APPLICATION

The present application claims priority to, and the benefit of, Korean Patent Application No. 10-2024-0080716, filed on Jun. 21, 2024, in the Korean Intellectual Property Office, the entire disclosure of which is incorporated herein by reference.

### BACKGROUND

### 1. Field

The present disclosure relates to a display device and a method for manufacturing the same.

### 2. Description of the Related Art

As the information society develops, the demand for display devices for displaying images is increasing in various forms. The display device may be a flat panel display device, such as a liquid crystal display, a field emission display, or a light-emitting display, and the like.

The light-emitting display device may include an organic light-emitting display device including an organic light-emitting diode element as a light-emitting element, and a micro light-emitting display device including a micro light-emitting diode element (hereinafter referred to as a micro light-emitting diode element) as a light-emitting element. Because the micro light-emitting diode element is made of inorganic materials, it may have fewer deterioration issues and a longer lifespan compared to organic light-emitting diode elements.

### SUMMARY

Aspects of embodiments of the present disclosure provide a display device and a method of manufacturing the same that may reduce the contact resistance caused by contaminant particles that may be generated during the heat pressing process of the light-emitting element and reduce the possibility of causing dark spots when the display panel is turned on.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, a display device includes a substrate, a pixel electrode and a common electrode above the substrate, a first reflective electrode and a second reflective electrode respectively above the pixel electrode and the common electrode, a first sacrificial electrode and a second sacrificial electrode respectively above the first reflective electrode and the second reflective electrode, an organic layer above the first sacrificial electrode and the second sacrificial electrode, a light-emitting element above the organic layer, and including a semiconductor stack, a first contact electrode, and a second contact electrode, a first connection electrode connecting the pixel electrode and the first contact electrode through a first connection hole in the organic layer and the first sacrificial electrode, and a second connection electrode connecting the common electrode and the second contact electrode through a second connection hole in the organic layer and the second sacrificial electrode.

The first connection hole may penetrate the organic layer and the first sacrificial electrode to expose the first reflective electrode, wherein the second connection hole penetrates the organic layer and the second sacrificial electrode to expose the second reflective electrode.

The first connection hole may be defined by a downwardly concave groove penetrating the organic layer above the first sacrificial electrode, wherein the second connection hole is defined by a downwardly concave groove penetrating the organic layer above the second sacrificial electrode.

The first connection hole and the second connection hole may have a stepped structure with a diameter that increases upwardly.

The first connection hole and the second connection hole may have step portions respectively defined by one of the reflective electrodes, one of the sacrificial electrodes, and the organic layer.

The display device may further include an element sacrificial electrode between the organic layer and the first contact electrode and the second contact electrode and completely overlapping one surface of the light-emitting element.

The light-emitting element may further include a conductive layer between the organic layer and the semiconductor stack, and a protective film on sides of the conductive layer and on sides of the semiconductor stack, wherein the first contact electrode is on the protective film, and is connected to the conductive layer exposed through the protective film, and wherein the second contact electrode is on the protective film, and is in a hole penetrating a portion of the conductive layer and the semiconductor stack.

The semiconductor stack may further include a first semiconductor layer above the organic layer, and including a semiconductor material doped with a first conductivity type dopant, an active layer above the first semiconductor layer, and a second semiconductor layer above the active layer, and including a semiconductor material doped with a second conductivity type dopant, wherein the first contact electrode is on a first side of the first semiconductor layer, on a first side of the active layer, and on a portion of the first side of the second semiconductor layer, and wherein the second contact electrode is on a second side of the first semiconductor layer, on a second side of the active layer, and on a portion of the second side of the second semiconductor layer.

According to an aspect of the present disclosure, a display device includes a substrate, a pixel electrode and a common electrode above the substrate, a first reflective electrode and a second reflective electrode respectively above the pixel electrode and the common electrode, a first sacrificial electrode above the first reflective electrode, and exposing a portion of a top surface of the first reflective electrode, a second sacrificial electrode above the second reflective electrode, and exposing a portion of a top surface of the second reflective electrode, an organic layer above the first sacrificial electrode and the second sacrificial electrode, a light-emitting element above the organic layer, and including a semiconductor stack, a first contact electrode, and a second contact electrode, a first connection electrode connecting the pixel electrode and the first contact electrode, and connected to the portion of the top surface of the first reflective electrode, and a second connection electrode connecting the common electrode and the second contact electrode, and connected to the portion of the top surface of the second reflective electrode.

According to an aspect of the present disclosure, a display device includes a substrate, a pixel electrode above the substrate, a reflective electrode respectively above the pixel electrode, a sacrificial electrode above the reflective electrode, an organic layer above the sacrificial electrode, and a light-emitting element above the organic layer and including a semiconductor stack and a contact electrode, and a connection electrode connecting the pixel electrode and the contact electrode through a connection hole in the organic layer and the sacrificial electrode.

The connection hole may penetrate the organic layer and the sacrificial electrode to expose the reflective electrode.

The connection hole may be defined by a groove penetrating the organic layer, and concave in a downward direction above the sacrificial electrode.

The light-emitting element may further include a protective film on a side of the semiconductor stack, wherein the contact electrode is on the protective film.

The semiconductor stack may further include a first semiconductor layer above the organic layer, and including a semiconductor material doped with a first conductivity type dopant, an active layer above the first semiconductor layer, and a second semiconductor layer above the active layer, and including a semiconductor material doped with a second conductivity type dopant, wherein the contact electrode is on an entire side surface of the first semiconductor layer, on an entire side surface of the active layer, and on a portion of a side surface of the second semiconductor layer.

According to an aspect of the present disclosure, a method of manufacturing a display device includes preparing light-emitting elements including a semiconductor stack, a first contact electrode, and a second contact electrode, forming a substrate on which a pixel electrode and a common electrode are arranged, stacking a first reflective electrode and a first sacrificial electrode above the pixel electrode, and a second reflective electrode and a second sacrificial electrode above the common electrode, forming an organic layer defining a through hole above the first sacrificial electrode and the second sacrificial electrode, transferring the light-emitting elements onto the organic layer so that the first contact electrode and the second contact electrode respectively face the pixel electrode and the common electrode, etching the first sacrificial electrode and the second sacrificial electrode exposed by the through hole to form a first connection hole and a second connection hole, forming a first connection electrode connecting the pixel electrode and the first contact electrode through the first connection hole, and forming a second connection electrode connecting the common electrode and the second contact electrode through the second connection hole.

The stacking the first reflective electrode and the first sacrificial electrode above the pixel electrode, and the second reflective electrode and the second sacrificial electrode above the common electrode, may include depositing a reflective material layer above a surface of the substrate to cover the pixel electrode and the common electrode, depositing a sacrificial material layer above the surface of the substrate to cover the reflective material layer, and partially etching the sacrificial material layer and the reflective material layer using a first chemical solution to which the first sacrificial electrode and the second sacrificial electrode react.

The transferring the light-emitting elements onto the organic layer may include arranging the light-emitting elements above the organic layer, and transferring the light-emitting elements onto the organic layer by heat pressing the light-emitting elements, wherein residual particles of an adhesive layer are on the organic layer, on the first sacrificial electrode, and on the second sacrificial electrode exposed by the through hole due to the heat pressing.

The method may further include removing the residual particles from the first sacrificial electrode and the second sacrificial electrode when the first sacrificial electrode and the second sacrificial electrode are etched.

During the forming of the second connection electrode, bottoms of the first connection hole and the second connection hole are open, a photoresist covers a side of the organic layer, and a stepped structure of connection holes with diameters increasing upwardly are formed by wet etching using the photoresist and a second chemical solution, wherein the second chemical solution includes a material that reacts with the first sacrificial electrode and the second sacrificial electrode, and that does not react with the first reflective electrode or the second reflective electrode.

The first connection hole and the second connection hole may have stepping portions respectively defined by the reflective electrode, the sacrificial electrode, and the organic layer, wherein a portion of the stepping portions defined by the sacrificial electrode has residual particles generated during transfer of the light-emitting elements.

According to an aspect of the present disclosure, an electronic device includes a display device includes a substrate, a pixel electrode and a common electrode above the substrate, a first reflective electrode and a second reflective electrode respectively above the pixel electrode and the common electrode, a first sacrificial electrode and a second sacrificial electrode respectively above the first reflective electrode and the second reflective electrode, an organic layer above the first sacrificial electrode and the second sacrificial electrode, a light-emitting element above the organic layer, and including a semiconductor stack, a first contact electrode, and a second contact electrode, a first connection electrode connecting the pixel electrode and the first contact electrode through a first connection hole in the organic layer and the first sacrificial electrode, and a second connection electrode connecting the common electrode and the second contact electrode through a second connection hole in the organic layer and the second sacrificial electrode.

The electronic device may include a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).

According to the display device and its manufacturing method according to embodiments, it is possible to reduce the possibility of dark spots occurring when the display panel is turned on due to contaminant particles that may be generated during the heat pressing process of the light-emitting element, and to improve the reliability of the panel.

However, the present disclosure is not limited to the aforementioned effects, and various other aspects are included in the present specification.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view illustrating a display device according to one or more embodiments.

FIG. 2 is a layout diagram illustrating a display device according to one or more embodiments.

FIG. 3 is a block diagram illustrating a display device according to one or more embodiments.

FIG. 4 is an equivalent circuit diagram illustrating a sub-pixel according to one or more embodiments.

FIG. 5 is a layout diagram illustrating pixels in a display area according to one or more embodiments.

FIG. 6 is a cross-sectional view illustrating a cross-section of a display panel taken along the line I-I′ in FIG. 5.

FIG. 7 is a cross-sectional view illustrating area A of FIG. 6 in detail.

FIG. 8 is a cross-sectional view illustrating another example of area A of FIG. 6 in detail.

FIG. 9 is a cross-sectional view illustrating another example of area A of FIG. 6 in detail.

FIG. 10 is a cross-sectional view illustrating another example of area A of FIG. 6 in detail.

FIG. 11 is a cross-sectional view illustrating another example of a cross-section of the display panel taken along the line I-I′ in FIG. 5.

FIG. 12 is a cross-sectional view illustrating area A2 in FIG. 11 in detail.

FIG. 13 is a layout diagram illustrating pixels of a display area according to one or more embodiments.

FIG. 14 is a cross-sectional view illustrating a cross-section of a display panel taken along the line I1-I1′ in FIG. 13.

FIG. 15 is a cross-sectional view illustrating area B1 in FIG. 14 in detail.

FIG. 16 is a cross-sectional view illustrating another example of a cross-section of the display panel taken along the line I1-I1′ in FIG. 13.

FIG. 17 is a cross-sectional view illustrating another example of area A2 of FIG. 16.

FIG. 18 is a flowchart illustrating a method of manufacturing a display device according to one or more embodiments.

FIGS. 19 to 30 are diagrams to illustrate a method of manufacturing a display device according to one or more embodiments.

FIGS. 31 and 32 are diagrams to illustrate another method of operation 150 of FIG. 18.

FIG. 33 is a view of a smart watch including a display device according to one or more embodiments;

FIGS. 34 and 35 are views of a virtual reality (VR) device including a display device according to one or more embodiments;

FIG. 36 is a view of a VR device including a display device according to one or more embodiments;

FIG. 37 is a view illustrating a vehicle instrument cluster and center fascia including display devices according to one or more embodiments; and

FIG. 38 is a view of a transparent display device including a display device according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same”. In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

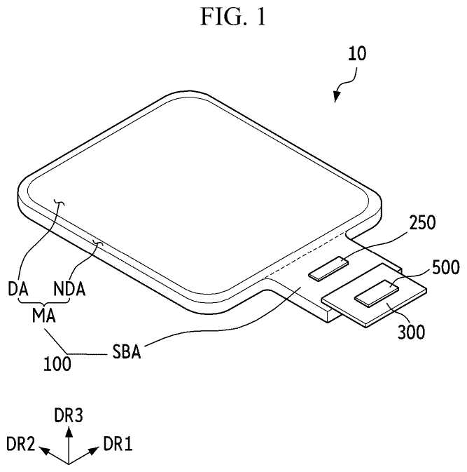

FIG. 1 is a perspective view illustrating a display device according to one or more embodiments.

Referring to FIG. 1, a display device 10 is a device for displaying video or still images, such as mobile phones, smart phones, tablet personal computers, and portable electronic devices, such as smart watches, watch phones, mobile communication terminals, electronic notebooks, e-books, portable electronic devices, such as portable multimedia players (PMP), navigation, and ultra mobile PCs (UMPC), as well as display screens for a variety of products, such as televisions, laptops, monitors, billboards, and the internet of things (IOT).

The display device 10 may be a light-emitting display device, such as an organic light-emitting display device utilizing an organic light-emitting diode, a quantum dot light-emitting display device including a quantum dot light-emitting layer, an inorganic light-emitting display device including an inorganic semiconductor, and a miniaturized light-emitting display device utilizing a micro or nano light-emitting diode (micro LED or nano LED). Hereinafter, the description mainly describes the display device 10 as a micro-light-emitting display device, but the present disclosure is not limited thereto. On the other hand, the subminiature light-emitting diode is described herein as a micro light-emitting element for convenience of explanation.

The display device 10 includes a display panel 100, a display-driving circuit 250, a circuit board 300, and a power supply circuit 500.

The display panel 100 may be formed as a rectangular-shaped plane having a short side in the first direction DR1, and a long side in the second direction DR2 that crosses the first direction DR1. A corner where the short side in the first direction DR1 and the long side in the second direction DR2 meet may be rounded to have a corresponding curvature or may be formed at a right angle. The planar shape of the display panel 100 is not limited to a rectangle, and may be formed in other polygonal, circular, or oval shapes. The display panel 100 may be formed flat but is not limited thereto. For example, the display panel 100 is formed at left and right ends and may include curved portions with a constant curvature or a changing curvature. Additionally, the display panel 100 may be flexible, such as to be able to be bent, curved, bent, folded, or rolled.

The substrate SUB of the display panel 100 may include a main area MA and a sub-area SBA.

The main area MA may include a display area DA that displays an image, and a non-display area NDA that is a peripheral area of the display area DA. The display area DA may include a plurality of pixels that display an image. Each pixel may include a plurality of sub-pixels. For example, each of the pixels may include a first sub-pixel that emits light of a first color, a second sub-pixel that emits light of a second color, and a third sub-pixel that emits light of a third color. However, the embodiments of the present disclosure are not limited thereto.

The sub-area SBA may protrude from one side of the main area MA in the second direction DR2. Although FIG. 1 illustrates the sub-area SBA being unfolded, the sub-area SBA may be bent, and in this case, may be located on the bottom surface of the display panel 100. When the sub-area SBA is bent, it may overlap the main area MA in the third direction DR3, which is the thickness direction of the display panel 100. The display-driving circuit 250 may be located in the sub-area SBA.

The display-driving circuit 250 may generate signals and voltages for driving the display panel 100. The display-driving circuit 250 may be formed as an integrated circuit (IC), and may be attached to the display panel 100 using a chip-on-glass (COG) method, a chip-on-plastic (COP) method, or an ultrasonic bonding method but is not limited thereto. For example, the display-driving circuit 250 may be attached to the circuit board 300 using a chip-on-film (COF) method.

The circuit board 300 may be attached to one end of the sub-area SBA of the display panel 100. As such, the circuit board 300 may be electrically connected to the display panel 100 and the display-driving circuit 250. The display panel 100 and the display-driving circuit 250 may receive digital video data, timing signals, and driving voltages through the circuit board 300. The circuit board 300 may be a flexible film, such as a flexible printed circuit board, a printed circuit board, or a chip on film.

The power supply circuit 500 may generate a plurality of panel driving voltages according to an external power supply voltage. The power supply circuit 500 may be formed as an integrated circuit (IC) and attached to the circuit board 300 using a COF method.

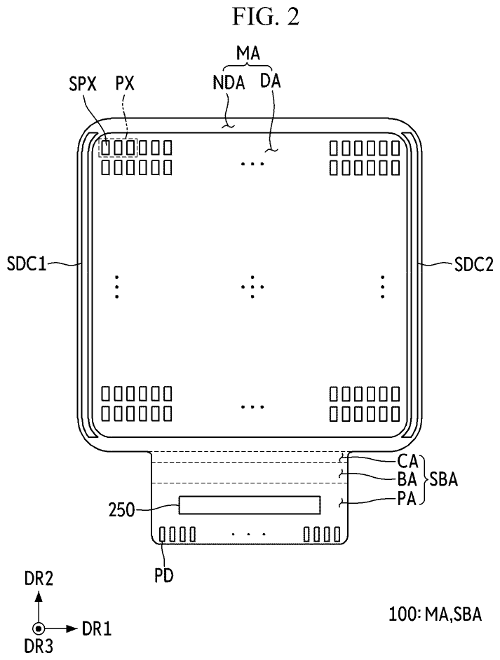

FIG. 2 is a layout diagram illustrating a display device according to one or more embodiments. FIG. 2 illustrates that the sub-area SBA is unfolded without being bent.

Referring to FIG. 2, the display panel 100 may include the main area MA and the sub-area SBA.

The main area MA may include the display area DA that displays an image and the non-display area NDA that is a peripheral area of the display area DA. The display area DA may occupy most of the main area MA. The display area DA may be placed in the center of the main area MA.

The display area DA may include a plurality of pixels PX for displaying an image, and each of the plurality of pixels PX may include a plurality of sub-pixels SPX. A pixel PX may be defined as a sub-pixel group of the smallest unit capable of expressing a white grayscale.

The non-display area NDA may be placed adjacent to the display area DA. The non-display area NDA may be an area outside the display area DA. The non-display area NDA may surround the display area DA (e.g., in plan view). The non-display area NDA may be an edge area of the display panel 100.

A first scan driver SDC1 and a second scan driver SDC2 may be located in the non-display area NDA. The first scan driver SDC1 is located on one side (for example, the left side) of the display panel 100, and the second scan driver SDC2 is located on the other side (for example, the right side) of the display panel 100. However, the present disclosure is not limited thereto.

Each of the first scan driver SDC1 and the second scan driver SDC2 may be electrically connected to the display-driving circuit 250 through scan fan-out lines. Each of the first scan driver SDC1 and the second scan driver SDC2 may receive a scan control signal from the display-driving circuit 250, may generate scan signals according to the scan control signal, and may output them to the scan lines.

The sub-area SBA may protrude from one side of the main area MA in the second direction DR2. The length of the sub-area SBA in the second direction DR2 may be less than the length of the main area MA in the second direction DR2. The length of the first direction DR1 of the sub-area SBA is less than the length of the first direction DR1 of the main area MA, or may be substantially equal to the length of the first direction DR1 of the main area MA. The sub-area SBA may be curved, and may be located at the lower portion of the display panel 100. In this case, the sub-area SBA may overlap the main area MA in the third direction DR3.

The sub-area SBA may include a connection area CA, a pad area PA, and a bending area BA.

The connection area CA is an area protruding from one side of the main area MA in the second direction DR2. One side of the connection area CA may be in contact with the non-display area NDA of the main area MA, and the other side of the connection area CA may be in contact with the bending area BA.

The pad area PA is an area where the pads PD and the display-driving circuit 250 are located. The display-driving circuit 250 may be attached to the driving pads of the pad area PA using a conductive adhesive member, such as an anisotropic conductive film. The circuit board 300 may be attached to the pads PD of the pad area PA using a conductive adhesive member, such as an anisotropic conductive film. One side of the pad area PA may be in contact with the bending area BA.

The bending area BA is a bent area. When the bending area BA is bent, the pad area PA may be located below the connection area CA and below the main area MA. The bending area BA may be located between the connection area CA and the pad area PA. One side of the bending area BA may be in contact with the connection area CA, and the other side of the bending area BA may be in contact with the pad area PA.

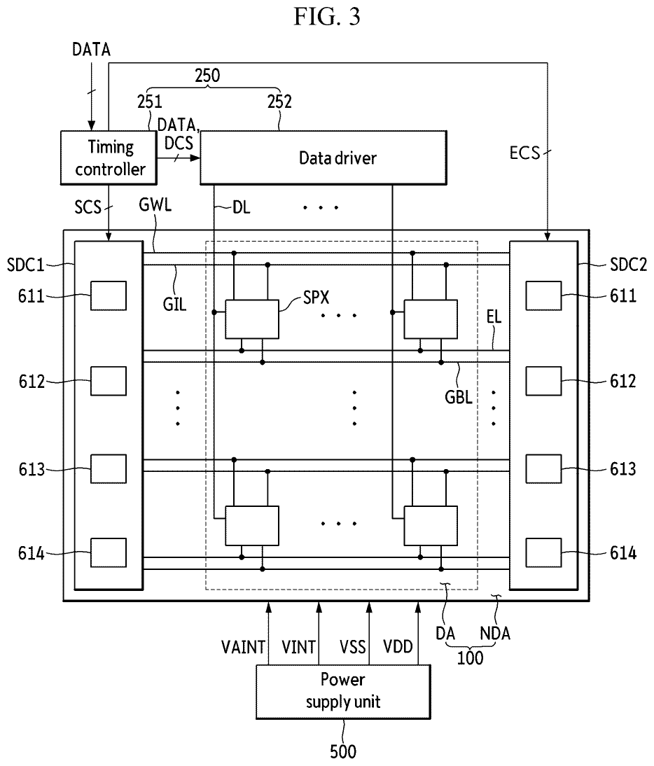

FIG. 3 is a block diagram illustrating a display device according to one or more embodiments.

Referring to FIG. 3, the display area DA includes a plurality of pixels PX, a plurality of scan lines, a plurality of emission control lines EL, and a plurality of data lines DL.

The plurality of pixels PX may be arranged in a matrix form in the first direction DR1 and the second direction DR2. The plurality of scan lines and the plurality of emission control lines EL may extend in the first direction DR1, and may be located in the second direction DR2. The plurality of data lines DL may extend in the second direction DR2, and may be located in the first direction DR1. The plurality of scan lines may include a plurality of write scan lines GWL, a plurality of control scan lines GCL, a plurality of initialization scan lines GIL, and a plurality of bias scan lines GBL.

Each of the plurality of sub-pixels SPX may be connected to a write scan line GWL from among the plurality of write scan lines GWL, a control scan line GCL from among the plurality of control scan lines GCL, an initialization scan line GIL from among the plurality of initialization scan lines GIL, a bias scan line GBL from among the plurality of bias scan lines GBL, an emission control line EL from among the plurality of emission control lines EL, and a data line DL from among the plurality of data lines DL. Each of the plurality of sub-pixels SPX may be supplied with a data voltage of the data line DL according to the write scan signal of the write scan line GWL and may emit light-emitting elements according to the data voltage.

The non-display area NDA includes a first scan driver SDC1, a second scan driver SDC2, and a display-driving circuit 250.

Each of the first scan driver SDC1 and the second scan driver SDC2 may include a write scan signal output 611, a control scan signal output 612, an initialization scan signal output 613, a bias scan signal output 614, and a light emission signal output 615. The write scan signal output 611, control scan signal output 612, initialization scan signal output 613, bias scan signal output 614, and light emission signal output 615 may each receive a scan-timing control signal SCS from the timing control circuit 400. The write scan signal output 611 may generate write scan signals according to the scan-timing control signal SCS of the timing control circuit 400, and may sequentially output them to the write scan lines GWL. The control scan signal output 612 may generate control scan signals according to the scan-timing control signal SCS, and may sequentially output them to the control scan lines GCL. The initialization scan signal output 613 may generate initialization scan signals according to the scan-timing control signal SCS, and may sequentially output them to the initialization scan lines GIL. The bias scan signal output 614 may generate bias scan signals according to the scan-timing control signal SCS, and may sequentially output them to the bias scan lines EBL. The light emission signal output 615 may generate emission control signals according to the scan-timing control signal SCS, and may sequentially output them to the emission control lines EL.

The display-driving circuit 250 includes a timing control circuit 251 and a data driver 252.

The data driver 252 may receive digital video data DATA and a data-timing control signal DCS from the timing control circuit 251. The data driver 252 converts digital video data DATA into analog data voltages according to the data-timing control signal DCS, and outputs them to the data lines DL. In this case, the sub-pixels SPX are selected by the write scan signals of the first scan driver SDC1 and the second scan driver SDC2, and data voltages may be supplied to the selected sub-pixels SPX.

The timing control circuit 251 may receive digital video data and timing signals from an external source. The timing control circuit 251 may generate the scan-timing control signal SCS and the data-timing control signal DCS to control the display panel 100 according to timing signals. The timing control circuit 400 may output the scan-timing control signal SCS to the first scan driver SDC1 and the second scan driver SDC2. The timing control circuit 251 may output digital video data DATA and a data-timing control signal DCS to the data driver 252.

The power supply circuit 500 may generate a plurality of panel driving voltages according to an external power supply voltage. For example, the power supply circuit 500 may generate and supply a first driving voltage VDD, a second driving voltage VSS, and a third driving voltage VINT.

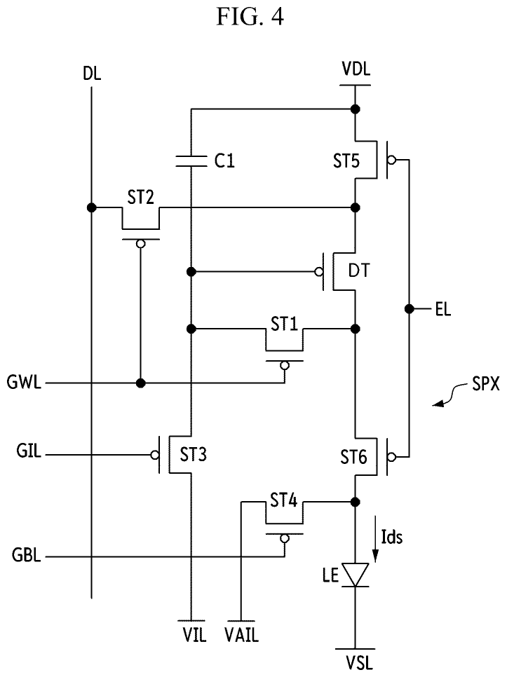

FIG. 4 is an equivalent circuit diagram illustrating a sub-pixel according to one or more embodiments.

Referring to FIG. 4, a sub-pixel SPX according to one or more embodiments may be connected to scan lines GWL, GIL, GCL, and GBL, an emission line EL, and a data line DL. For example, the sub-pixel SPX may be connected to a write scan line GWL, an initialization scan line GIL, a control scan line GCL, a bias scan line GBL, an emission line EL, and a data line DL.

The sub-pixel SPX1 according to one or more embodiments includes a driving transistor DT, switch elements, a capacitor C1, and a light-emitting element LE. The switch elements include first to sixth transistors ST1, ST2, ST3, ST4, ST5, and ST6.

The driving transistor DT includes a gate electrode, a conductive layer, and a second electrode. The driving transistor DT controls the drain-source current (Ids, hereinafter referred to as “driving current”) flowing between the conductive layer and the second electrode according to the data voltage applied to the gate electrode.

The light-emitting element LE may be a micro light-emitting diode. The light-emitting element LE emits light according to the driving current Ids. The anode electrode of the light-emitting element LE is connected to the conductive layer of the fourth transistor ST4 and the second electrode of the sixth transistor ST6, and the cathode electrode may be connected to a second power supply line VSL to which the second power supply voltage is applied.

The capacitor C1 is formed between the second electrode of the driving transistor DT and the first power supply line VDL to which the first power supply voltage is applied. The first power supply voltage may be at a higher level than the second power supply voltage. One electrode of the capacitor C1 may be connected to the second electrode of the driving transistor DT, and the other electrode may be connected to the first power supply line VDL.

As shown in FIG. 4, the first to sixth transistors ST1, ST2, ST3, ST4, ST5, and ST6 and the driving transistor DT may all be formed as p-type metal-oxide-semiconductor field-effect transistor (MOSFET). In this case, the active layer of each of the first to sixth transistors ST1, ST2, ST3, ST4, ST5, and ST6 and the driving transistor DT may be formed of polysilicon.

The gate electrode of the first transistor ST1 and the gate electrode of the second transistor ST2 may be connected to the write scan line GWL, the gate electrode of the third transistor ST3 may be connected to the initialization scan line GIL, and the gate electrode of the fourth transistor ST4 may be connected to the bias scan line GBL. Because the first to sixth transistors ST1, ST2, ST3, ST4, ST5, and ST6 are formed as p-type MOSFET, the control scan line GCL, the initialization scan line GIL, the write scan line GWL, the bias scan line GBL, and the light emission line EL may be turned on when a scan signal and a light-emitting signal of the gate low voltage are applied, respectively. One electrode of the third transistor ST3 and one electrode of the fourth transistor ST4 may be connected to the initialization voltage line VIL.

Alternatively, the driving transistor DT, the second transistor ST2, the fourth transistor ST4, the fifth transistor ST5, and the sixth transistor ST6 may be formed of a p-type MOSFET, and the first transistor ST1 and the third transistor ST3 may be formed of an n-type MOSFET. The active layer of each of the driving transistor DT, the second transistor ST2, the fourth transistor ST4, the fifth transistor ST5, and the sixth transistor ST6 formed of a p-type MOSFET may be formed of polysilicon, and the active layer of each of the first and third transistors ST1 and ST3 formed as an n-type MOSFET may be formed of an oxide semiconductor.

In this case, because the first transistor ST1 and the third transistor ST3 are formed as n-type MOSFET, the first transistor ST1 may be turned on when a scan signal of a gate high voltage is applied, and the third transistor ST3 may be turned on when an initialization scan signal with the gate high voltage is applied. In comparison, the second transistor ST2, the fourth transistor ST4, the fifth transistor ST5, and the sixth transistor ST6 are formed as p-type MOSFET, so that they may be turned on when a scan signal of the gate low voltage and a light emission control signal are applied.

Alternatively, the fourth transistor ST4 may be formed of an n-type MOSFET, so that each active layer of the fourth transistor ST4 may be formed of an oxide semiconductor. When the fourth transistor ST4 is formed of an n-type MOSFET, it may be turned on when a scan signal of the gate high voltage is applied.

Alternatively, the first to sixth transistors ST1, ST2, ST3, ST4, ST5, and ST6 and the driving transistor DT may all be formed as n-type MOSFET. In this case, the active layer of each of the first to sixth transistors ST1, ST2, ST3, ST4, ST5, and ST6 and the driving transistor DT may be formed of an oxide semiconductor.

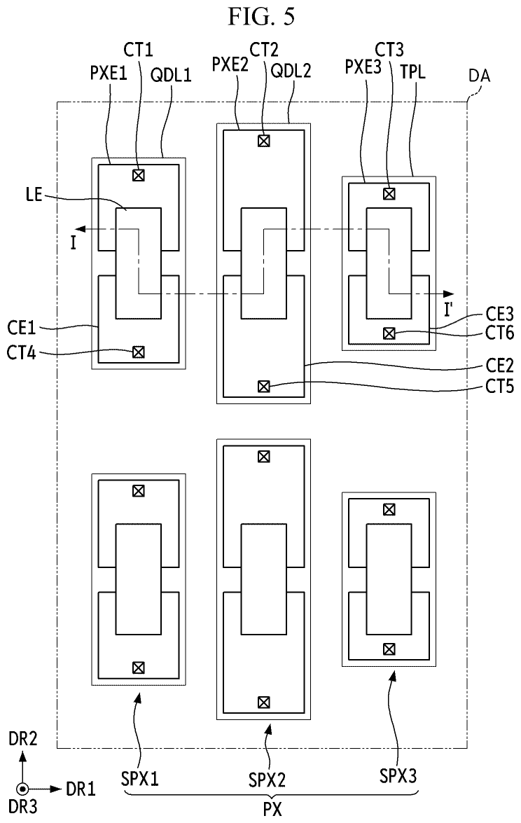

FIG. 5 is a layout diagram illustrating pixels in a display area according to one or more embodiments.

Referring to FIG. 5, each of the plurality of pixels PX of the display area DA may include three sub-pixels SPX1, SPX2, and SPX3, but the present disclosure is not limited thereto and may include four sub-pixels. When each of the plurality of pixels PX includes three sub-pixels SPX1, SPX2, and SPX3, the first sub-pixel SPX1, the second sub-pixel SPX2, and the third sub-pixel SPX3 may include.

The plurality of pixels PX may be arranged in a matrix form. In each of the plurality of pixels PX, the first sub-pixel SPX1, the second sub-pixel SPX2, and the third sub-pixel SPX3 may be arranged in a first direction DR1.

When each of the plurality of pixels PX includes three sub-pixels SPX1, SPX2, and SPX3, the first sub-pixel SPX1 may emit light of a first color, and the second sub-pixel SPX2 may emit light of a second color, and the third sub-pixel SPX3 may emit light of a third color. Here, the first color light may be light in a blue wavelength band, the second color light may be light in a green wavelength band, and the third color light may be light in a red wavelength band. For example, the blue wavelength band may refer to light having a main peak wavelength in the wavelength band from approximately 370 nm to approximately 460 nm, the green wavelength band may refer to light having a main peak wavelength in the wavelength band from approximately 480 nm to approximately 560 nm, and the red wavelength band may refer to light having a main peak wavelength in the wavelength band from approximately 600 nm to approximately 750 nm.

Alternatively, when each of the plurality of pixels PX includes four sub-pixels, the first sub-pixel may emit light of a first color, the second and fourth sub-pixels may emit light of a second color, and the third sub-pixel may emit light of a third color. Alternatively, the first sub-pixel may emit light of a first color, the second sub-pixel may emit light of a second color, the third sub-pixel may emit light of a third color, and the fourth sub-pixel may emit light of a fourth color. In this case, the fourth color light may be white light.

The first sub-pixel SPX1 includes a first pixel electrode PXE1, a plurality of light-emitting elements LE, and a first light conversion layer QDL1. The second sub-pixel SPX2 includes a second pixel electrode PXE2, the plurality of light-emitting elements LE, and the second light conversion layer QDL2. The third sub-pixel SPX3 includes a third pixel electrode PXE3, a plurality of light-emitting elements LE, and a third light conversion layer QDL3.

In each of the first sub-pixel SPX1, the second sub-pixel SPX2, and the third sub-pixel SPX3, the pixel electrodes PXE1, PXE2, and PXE3 and the common electrode CE may be arranged in the second direction DR2. Each of the pixel electrodes PXE1, PXE2, and PXE3 and the common electrodes CE1, CE2, and CE3 may have a rectangular planar shape, but but the present disclosure is not limited thereto. The area of the first pixel electrode PXE1 may be equal to the area of the first common electrode CE1, the area of the second pixel electrode PXE2) may be equal to the area of the second common electrode CE2, and the area of the third pixel electrode PXE3 may be equal to the area of the third common electrode CE3, but the embodiments of the present disclosure are not limited thereto.

For example, as shown in FIG. 5, when the light conversion efficiency of the second light conversion layer QDL2 is lower than the light conversion efficiency of the first light conversion layer QDL1, the area of the second pixel electrode PXE2 may be larger than the area of the first pixel electrode PXE1, and the area of the second common electrode CE2 may be larger than the area of the first common electrode CE1. Also, while the light transmission layer TPL transmits the light of the light-emitting element LE as it is, and the first light conversion layer QDL1 converts light, the area of the first pixel electrode PXE1 may be larger than the area of the third pixel electrode PXE3, and the area of the first common electrode CE1 may be larger than the area of the third common electrode CE3.

Each of the pixel electrodes PXE1, PXE2, and PXE3 may be electrically connected to at least one transistor through the pixel connection hole CT1, CT2, and CT3. For example, each of the pixel electrodes PXE1, PXE2, and PXE3 may be electrically connected to the second electrode of the fourth transistor (ST4 in FIG. 4) and the second electrode of the sixth transistor (ST6 in FIG. 4) of the corresponding sub-pixel.

The first common electrode CE1 may be connected to the second power supply line VSL to which the second driving voltage VSS is applied through a first common connection hole CT4. The second common electrode CE2 may be connected to the second power supply line VSL through a second common connection hole CT5. The third common electrode CE3 may be connected to the second power supply line VSL through a third common connection hole CT6. Therefore, the second driving voltage VSS may be applied to each of the common electrodes CE1, CE2, and CE3. The pixel electrodes PXE1, PXE2, and PXE3 may be referred to as an anode electrode or a first electrode, and the common electrodes CE1, CE2, and CE3 may be referred to as a cathode electrode or a second electrode.

The plurality of light-emitting elements LE may be located on the pixel electrodes PXE1, PXE2, and PXE3 and the common electrodes CE1, CE2, and CE3 (as used herein, “located on” may mean “above”). Each of the plurality of light-emitting elements LE may have a rectangular planar shape, but the embodiments of the present disclosure are not limited thereto. For example, each of the plurality of light-emitting elements LE may have a circular planar shape.

The first light conversion layer QDL1 may completely overlap the plurality of light-emitting elements LE of the first sub-pixel SPX1. The first light conversion layer QDL1 may convert or shift the peak wavelength of incident light into light of another corresponding peak wavelength and emit it. For example, the first light conversion layer QDL1 may convert or shift the third light emitted from the plurality of light-emitting elements LE of the first sub-pixel SPX1 into first light.

The second light conversion layer QDL2 may completely overlap the plurality of light-emitting elements LE of the second sub-pixel SPX2. The area of the second light conversion layer QDL2 may be larger than the area of the second pixel electrode PXE2. The second light conversion layer QDL2 may convert or shift the peak wavelength of incident light into light of another corresponding peak wavelength and emit it. For example, the second light conversion layer QDL2 may convert or shift the third light emitted from the plurality of light-emitting elements LE of the second sub-pixel SPX2 into second light.

The light transmission layer TPL may completely overlap the plurality of light-emitting elements LE of the third sub-pixel SPX3. The light transmission layer TPL may transmit incident light as it is. For example, the light transmission layer TPL may directly transmit the third light emitted from the plurality of light-emitting elements LE of the third sub-pixel SPX3.

When the light-emitting element LE of the first sub-pixel SPX1 emits light of a first color, the light-emitting element LE of the second sub-pixel SPX2 emits light of a second color, and the light-emitting element LE of the third sub-pixel SPX3 emits light of a third color, the light conversion layers QDL1 and QDL2 and the light transmission layer TPL may be omitted.

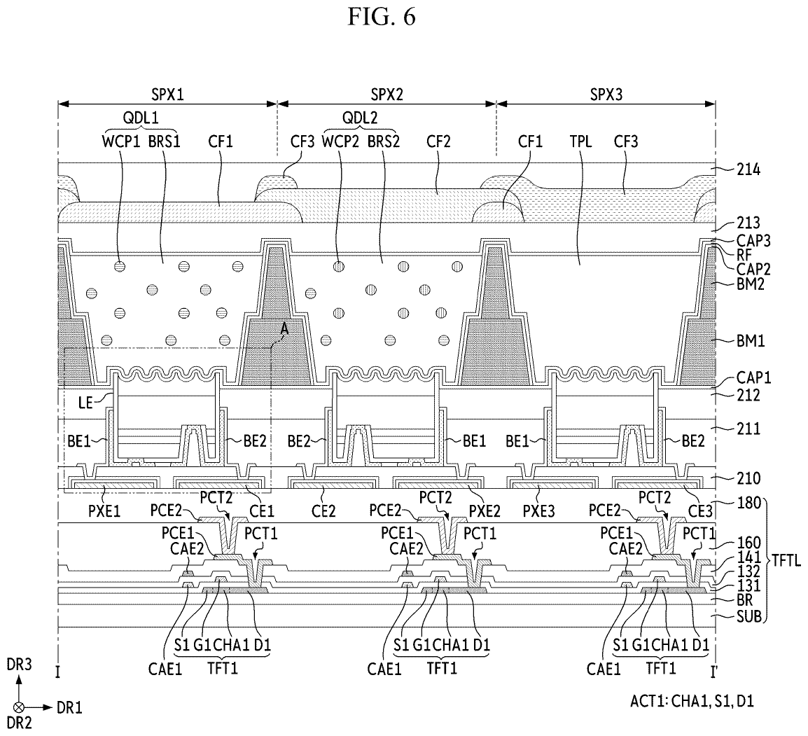

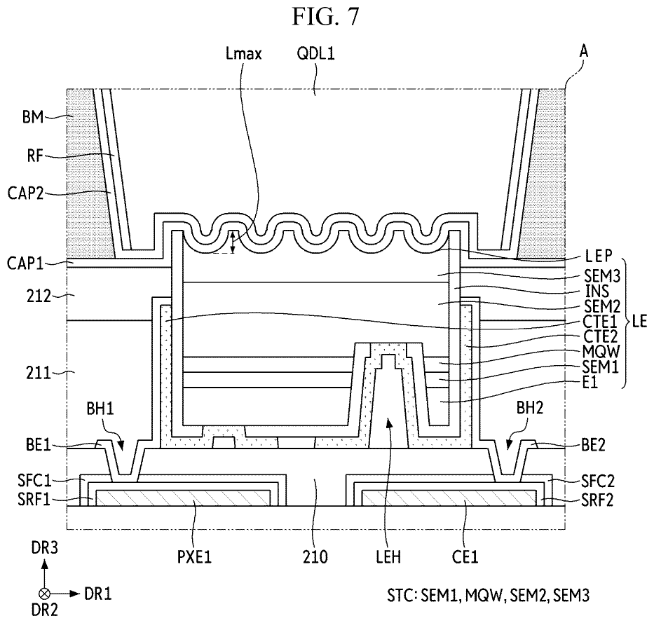

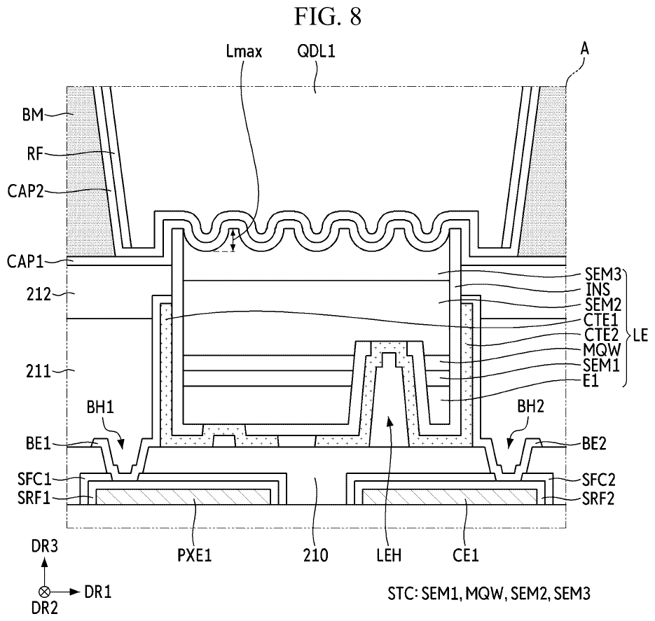

FIG. 6 is a cross-sectional view illustrating a cross-section of a display panel taken along the line I-I′ in FIG. 5. FIG. 7 is a cross-sectional view illustrating area A of FIG. 6 in detail. FIG. 8 is a cross-sectional view illustrating another example of area A of FIG. 6 in detail.

Referring to FIGS. 6 to 7, a substrate SUB may be made of an insulating material, such as glass, polymer resin, or the like. If the substrate SUB is made of polymer resin, it may be a flexible substrate that may be stretched. The polymer resin may be acrylic resin, epoxy resin, phenolic resin, polyamide resin, polyimide resin, or the like.

A barrier film BR may be located on the substrate SUB. The barrier film BR is a film that protects the transistors of the thin film transistor layer TFTL and the light-emitting element layer EML from moisture penetrating through the substrate SUB, which is vulnerable to moisture penetration. The barrier film BR may be composed of a plurality of inorganic films stacked alternately.

A thin film transistor TFT1 may be located on the barrier film BR. The thin film transistor TFT1 may be either the fourth transistor ST4 or the sixth transistor ST6 shown in FIG. 4. The thin film transistor TFT1 may include a first active layer ACT1 and a first gate electrode G1.

The first active layer ACT1 of the thin film transistor TFT1 may be located on the barrier film BR. The first active layer ACT1 of the thin film transistor TFT1 may include polycrystalline silicon, monocrystalline silicon, low-temperature polycrystalline silicon, or amorphous silicon. Alternatively, the first active layer ACT1 of the thin film transistor TFT1 may include an oxide semiconductor including IGZO (indium (In), gallium (Ga), zinc (Zn), and oxygen (O)), IGZTO (indium (In), gallium (Ga), zinc (Zn), tin (Sn), and oxygen (O)), or IGTO (indium (In), gallium (Ga), tin (Sn), and oxygen (O)).

The first active layer ACT1 may include a first channel area CHA1, a first source area S1, and a first drain area D1. The first channel area CHA1 may be an area overlapping the first gate electrode G1 in the third direction DR3, which is the thickness direction of the substrate SUB. The first source area S1 may be located on one side of the first channel area CHA1, and the first drain area D1 may be located on the other side of the first channel area CHA1. The first source area S1 and the first drain area D1 may be areas that do not overlap with the first gate electrode G1 in the third direction DR3. The first source area S1 and the first drain area D1 may be conductive areas in which semiconductor materials are doped with ions.

A first gate-insulating film 131 may be located on the first channel area CHA1, the first source area S1, and the first drain area D1 of the thin film transistor TFT1.

A first gate metal layer may be located on a first gate-insulating film 131. The first gate metal layer may include the first gate electrode G1 and the first capacitor electrode CAE1 of the thin film transistor TFT1. The first gate electrode G1 may overlap the first active layer ACT1 in the third direction DR3. In FIG. 6, the first gate electrode G1 and the first capacitor electrode CAE1 are shown to be located apart from each other, but the first gate electrode G1 and the first capacitor electrode CAE1 may be connected to each other.

A second gate-insulating film 132 may be located on the first gate electrode G1 and the first capacitor electrode CAE1 of the thin film transistor TFT1.

A second gate metal layer may be located on the second gate-insulating film 132. The second gate metal layer may include a second capacitor electrode CAE2. The second capacitor electrode CAE2 may overlap the first capacitor electrode CAE1 of the thin film transistor TFT1 in the third direction DR3. Because the second gate-insulating film 132 has a corresponding dielectric constant, the capacitor (C1 in FIG. 4) may be formed by the first capacitor electrode CAE1, the second capacitor electrode CAE2, and the second gate-insulating film 132 located between them.

A first interlayer insulating film 141 may be located on the second capacitor electrode CAE2.

A first data metal layer may be located on the first interlayer insulating film 141. The first data metal layer may include a first source connection electrode PCE1. The first source connection electrode PCE1 may be connected to the first drain area D1 of the first active layer ACT1 through a first source contact hole PCT1 penetrating the first gate-insulating film 131, the second gate-insulating film 132, and the first interlayer insulating film 141.

A first planarization organic film 160 may be located on the first source connection electrode PCE1 to planarize a step caused by the thin film transistor TFT1.

A second data metal layer may be located on the first planarization organic film 160. The second data metal layer may include a second source connection electrode PCE2. The second source connection electrode PCE2 may be connected to the first source connection electrode PCE1 through a second source contact hole PCT2 penetrating the first planarization organic film 160.

A second planarization organic film 180 may be located on the second source connection electrode PCE2.

The barrier film BR, the first gate-insulating film 131, the second gate-insulating film 132, and the first interlayer insulating film 141 may be formed from an inorganic film, for example, silicon nitride (SiNₓ), silicon oxide (SiON), silicon oxide (SiOₓ), titanium oxide (TiOₓ), or aluminum oxide (AlOₓ).

The first gate metal layer, the second gate metal layer, the first data metal layer, and the second data metal layer may be formed as a single layer or multiple layers of any one of molybdenum (Mo), aluminum (Al), chromium (Cr), gold (Au), titanium (Ti), nickel (Ni), neodymium (Nd), or copper (Cu), or an alloy thereof.

The first planarization organic film 160 and the second planarization organic film 180 may be formed of an organic film, such as an acrylic resin, an epoxy resin, a phenolic resin, a polyamide resin, a polyimide resin, or the like.

A light-emitting element layer may be located on the second planarization organic film 180. The light-emitting element layer may include pixel electrodes PXE1, PXE2, PXE3, light-emitting elements LE, a common electrode CE, and an organic layer 210.

A pixel electrode layer including the pixel electrodes PXE1, PXE2, and PXE3 and the common electrodes CE1, CE2, and CE3 may be located on a second planarization organic film 180.

Each of the first pixel electrode PXE1, the second pixel electrode PXE2, and the third pixel electrode PXE3 may be connected to the second source connection electrode PCE2 through a connection hole (CT1, CT2, and CT3 in FIG. 5) penetrating the second planarized organic film 180. Each of the pixel electrodes PXE1, PXE2, and PXE3 may be connected to a first source area S1 or a first drain area D1 of the thin film transistor TFT1 through the first source connection electrode PCE1 and the second source connection electrode PCE2. Therefore, a voltage controlled by the thin film transistor TFT1 may be applied to each of the pixel electrodes PXE1, PXE2, and PXE3.

The common electrodes CE1, CE2, and CE3 are connected to the second power supply line (VSL in FIG. 4) to which the second driving voltage (VSS in FIG. 3) is applied through the common connection hole (CT, CT5, and CT6 in FIG. 5). The second common electrode CE2 may be connected to the second power supply line VSL through the second common connection hole CT5. The third common electrode CE3 may be connected to the second power supply line VSL through the third common connection hole CT6. Therefore, the second driving voltage VSS may be applied to each of the common electrodes CE1, CE2, and CE3.

The pixel electrode layer may be formed as a single layer or multiple layers of any one of molybdenum (Mo), aluminum (Al), chromium (Cr), gold (Au), titanium (Ti), nickel (Ni), neodymium (Nd), or copper (Cu), or alloys thereof. For example, the pixel electrode layer may be made of copper (Cu) with low sheet resistance to lower the resistance of each of the pixel electrodes PXE1, PXE2, and PXE3.

An organic layer 210 may be located on each pixel electrode layer. The organic layer 210 serves to temporarily fix or adhere the top member (eg, light-emitting element LE). For example, the organic layer 210 may be a film for pseudo-adhering the top member (e.g., light-emitting element LE) to each of the pixel electrodes PXE1, PXE2, and PXE3 and the common electrodes CE1, CE2, and CE3. To facilitate pseudo-adhesion, the thickness of the organic layer 210 may be greater than the thickness of each of the pixel electrodes PXE1, PXE2, and PXE3 and the common electrodes CE1, CE2, and CE3 and greater than the thickness of the contact electrode CTE. The thickness of the organic layer 210 may be about 2 μm but is not limited thereto.

The organic layer 210 may be a photosensitive organic layer, such as photoresist. Alternatively, the organic layer 210 may be formed from an acrylic resin, an epoxy resin, a phenolic resin, a polyamide resin, a polyimide resin, or the like.

The plurality of light-emitting elements LE may be located on the organic layer 210. FIGS. 6 and 7 illustrate that the light-emitting element LE is a flip-type micro LED. The flip-type micro LED refers to an LED in which contact electrodes CTE1 and CTE2 are formed on one side (e.g., the bottom side) of the light-emitting element LE.

The light-emitting element LE may include a substantially vertical side surface as shown in FIG. 7. For example, the light-emitting element LE may be patterned through vertical etching and may have a rectangular or square cross-sectional shape where the width of the top surface and the width of the bottom surface are substantially the same. The height of the light-emitting element LE may be about 5.5 μm but is not limited thereto.

Each of the plurality of light-emitting elements LE may be formed of an inorganic material, such as gallium nitride (GaN).

Each of the plurality of light-emitting elements LE may be formed by growing on a semiconductor substrate, such as a silicon substrate or sapphire substrate. The plurality of light-emitting elements LE may be transferred onto the pixel electrode layer of the display panel 100 directly from the semiconductor substrate or through a relay substrate. Alternatively, the plurality of light-emitting elements LE may be transferred onto the pixel electrodes PXE1, PXE2, and PXE3 of the display panel 100 through an electrostatic method using an electrostatic head or a stamp method using an elastic polymeric material, such as PDMS (polydimethylsiloxane) or silicone as a transfer substrate.

As shown in FIG. 7, a reflective electrode SRF (e.g., SRF1 and SRF2) may be located on the top surfaces of the pixel electrode PXE1 and the common electrode CE1. The reflective electrode SRF may be formed as a single layer of a highly reflective metal or may be formed as a multilayer, such as titanium (Ti)/aluminum (Al)/titanium (Ti) or ITO/aluminum (Al)/ITO.

A sacrificial electrode SFC (e.g., SFC1 and SFC2) may be located on the reflective electrode SRF. The sacrificial electrode SFC may be formed of a conductive metal.

In one or more embodiments, the reflective electrode SRF may be formed from a multilayer of ITO/Aluminum (Al)/ITO, and the sacrificial electrode (SFC) may be formed from IZO. The reflective electrode SRF ITO/aluminum (Al)/ITO may have a thickness of approximately 50 Å/850 Å/115 Å, respectively but is not limited thereto. The sacrificial electrode SFC may be about 100 Å but is not limited thereto. However, as the sacrificial electrodes SFC1 and SFC2 become thicker, the probability of cracks occurring in the connection electrodes BE1 and BE2 at the boundary between the organic layer 210 and the sacrificial electrodes SFC1 and SFC2 may increase.

The light-emitting element LE may include a conductive layer E1, a semiconductor stack STC, a first contact electrode CTE1, a second contact electrode CTE2, and a protective film INS. The semiconductor stack STC may include a first semiconductor layer SEM1, an active layer MQW, a second semiconductor layer SEM2, and a third semiconductor layer SEM3 sequentially arranged in the third direction DR3.

The conductive layer E1 may be located on the lower surface of the first semiconductor layer SEM1. Although FIG. 7 illustrates that the conductive layer E1 covers the entire lower surface of the first semiconductor layer SEM1, the embodiments of the present disclosure are not limited thereto. In one example, the conductive layer E1 may be located on a portion of the lower surface of the first semiconductor layer SEM1. The conductive layer E1 may include any one of molybdenum (Mo), aluminum (Al), chromium (Cr), gold (Au), titanium (Ti), nickel (Ni), neodymium (Nd), or copper (Cu).

The first semiconductor layer SEM1 may be located on the conductive layer E1. The first semiconductor layer SEM1 may include a semiconductor material layer doped with a first conductive dopant, such as magnesium (Mg), zinc (Zn), calcium (Ca), strontium (Sr), barium (Ba), or the like, for example gallium nitride (GaN).

The active layer MQW may be located on the first semiconductor layer SEM1. The active layer MQW may emit light by combining electron-hole pairs according to an electrical signal applied through the first semiconductor layer SEM1 and the second semiconductor layer SEM2.

The active layer MQW may include a material having a single or multi-quantum well structure. When the active layer MQW includes a material having a multi-quantum well structure, it may have a structure in which a plurality of well layers and barrier layers are alternately stacked. At this time, the well layer may be formed of indium gallium nitride (InGaN), and the barrier layer may be formed of gallium nitride (GaN) or aluminum gallium nitride (AlGaN), but embodiments of the present disclosure are not limited thereto.

Alternatively, the active layer MQW may have a structure in which semiconductor materials having a high band gap energy and semiconductor materials having a low band gap energy are alternately stacked with each other, may include other Group III to Group V semiconductor materials according to the wavelength range of emitted light.

In one or more embodiments, when the active layer MQW includes InGaN, the color of the emitted light may vary depending on the content of indium (In). For example, as the content of indium (In) increases, the wavelength band of light emitted by the active layer may shift to the red wavelength band, and as the content of indium (In) decreases, the wavelength band of light emitted by the active layer may shift to the blue wavelength band. For example, the content of indium (In) in the active layer MQW of the light-emitting element LE that emits the third light (light in the blue wavelength band) may be approximately 10 wt % to approximately 20 wt %.

The second semiconductor layer SEM2 may be located on the first semiconductor layer SEM1. The second semiconductor layer SEM2 may be a semiconductor material layer doped with a second conductivity type dopant, such as silicon (Si), germanium (Ge), tin (Sn), etc., for example, gallium nitride (GaN).

The third semiconductor layer SEM3 may be located on the second semiconductor layer SEM2. The third semiconductor layer SEM3 is a semiconductor material layer in which the n-type dopant is lower than a corresponding threshold value, and may be referred to as an un-doped semiconductor layer. For example, the third semiconductor layer SEM3 may be indium aluminum gallium nitride (InAlGaN), gallium nitride (GaN), aluminum gallium nitride (AlGaN), indium gallium nitride (InGaN), aluminum nitride (AlN), or indium nitride (InN), where the n-type dopant is below a corresponding threshold. The third semiconductor layer SEM3 may be omitted.

An electron-blocking layer may be located between the first semiconductor layer SEM1 and the active layer MQW. The electron-blocking layer may be a layer to suppress or prevent too many electrons from flowing into the active layer MQW. For example, the electron-blocking layer may be aluminum gallium nitride (AlGaN) or p-type aluminum gallium nitride (AlGaN) doped with p-type magnesium (Mg). The electronic blocking layer may be omitted.

A superlattice layer may be located between the active layer MQW and the second semiconductor layer SEM2. The superlattice layer may be a layer for relieving stress between the second semiconductor layer SEM2 and the active layer MQW. For example, the superlattice layer may be aluminum gallium nitride (AlGaN) or p-type aluminum gallium nitride (AlGaN) doped with p-type magnesium (Mg). The superlattice layer may be omitted.

A light extraction patterns LEP may be formed on the top surface of the semiconductor stack STC. In one example, the light extraction patterns LEP may be formed on the top surface of the third semiconductor layer SEM3.

The light extraction patterns LEP may be patterns to increase the efficiency of light emitted from the top surface of the light-emitting element LE. The light extraction patterns LEP may be concave pattern formed as a hemisphere or a semi-ellipsoid. The light extraction patterns LEP may be concave patterns with a semicircular or semielliptical cross-sectional shape. The maximum length Lmax of the light extraction patterns LEP in the third direction DR3 may be approximately 100 nm. Further, the distance between adjacent light extraction patterns LEP may be approximately 100 nm or less. In other embodiments, the light extraction patterns LEP may be omitted.

The light extraction patterns LEP may be formed from an organic film, such as an acrylic resin, epoxy resin, phenolic resin, polyamide resin, polyimide resin, or the like. Alternatively, the light extraction patterns LEP may be formed from inorganic films, for example, silicon nitride (SiNₓ), silicon oxide (SiON), silicon oxide (SiOₓ), titanium oxide (TiOₓ), or aluminum oxide (AlOₓ).

The protective film INS may be a film to protect the bottom and side surfaces of the light-emitting element LE. The protective film INS may be located on the bottom and side surfaces of the conductive layer E1 and on the side surfaces of the semiconductor stack STC. For example, the protective film INS may be located on the bottom and side surfaces of the conductive layer E1, on the side surface of the first semiconductor layer SEM1, on the side surface of the active layer MQW, on the side surface of the second semiconductor layer SEM2, and on the side surface of the third semiconductor layer SEM3. The protective film INS may be formed of an inorganic film, for example, silicon nitride (SiNₓ), silicon oxide (SiON), silicon oxide (SiOₓ), titanium oxide (TiOₓ), or aluminum oxide (AlOₓ).

A hole LEH exposing the second semiconductor layer SEM2 may be formed through the conductive layer E1, the first semiconductor layer SEM1, and the active layer MQW of the light-emitting element LE. The hole LEH may have a rectangular plan shape, but embodiments of the present disclosure are not limited thereto. In one example, the hole LEH may have a polygonal plan shape, such as a circle, an oval, or a square.

In addition, the protective film INS may be located on the sidewall of the conductive layer E1 exposed in the hole LEH, the sidewall of the first semiconductor layer SEM1, and the sidewall of the active layer MQW. The protective film INS may not cover the second semiconductor layer SEM2 in the hole LEH. Therefore, the second semiconductor layer SEM2 may be exposed without being covered by the protective film INS.

The first contact electrode CTE1 may be located on at least one side of the semiconductor stack STC and on at least one side and bottom of the conductive layer E1. The first contact electrode CTE1 may be located on the exposed bottom surface of the conductive layer E1 that is not covered by the protective film INS. Therefore, the first contact electrode CTE1 may be electrically connected to the conductive layer E1.

The second contact electrode CTE2 may be located on at least one side of the semiconductor stack STC, and on at least one side and bottom of the conductive layer E1. In this case, the first contact electrode CTE1 may be located on the first side of the semiconductor stack STC and on a first side of the conductive layer E1, while the second contact electrode CTE2 may be located on a second side of the semiconductor stack STC and on a second side of the conductive layer E1.

The second contact electrode CTE2 may be located on the protective film INS located in the hole LEH and on the second semiconductor layer SEM2 exposed in the hole LEH without being covered by the protective film INS. Therefore, the second contact electrode CTE2 may be electrically connected to the second semiconductor layer SEM2 in the hole LEH.

The first contact electrode CTE1 and the second contact electrode CTE2 may be located on at least a portion of the side surface of the semiconductor stack STC. Among the side surfaces of the semiconductor stack STC, at least an area adjacent to the top surface of the semiconductor stack STC may be exposed without being covered by the first and second contact electrodes CTE1 and CTE2. For example, the first and second contact electrodes CTE1 and CTE2 may be spaced apart from the top surface of the semiconductor stack STC in the third direction DR3.

The first contact electrode CTE1 and the second contact electrode CTE2 may include any one of molybdenum (Mo), aluminum (Al), chromium (Cr), gold (Au), titanium (Ti), nickel (Ni), neodymium (Nd), or copper (Cu). For example, the first contact electrode CTE1 and the second contact electrode CTE2 may be formed from a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO) to increase reflectivity.

Each of the first and second contact electrodes CTE1 and CTE2 may be located on three sides of the semiconductor stack STC. For example, when the semiconductor stack STC includes first to fourth sides, the first contact electrode CTE1 may be located on the first side, the second side, and the third side, and the second contact electrode CTE2 may be located on the second side, third side, and fourth side.

The first connection electrode BE1 connects the first contact electrode CTE1 of the light-emitting element LE and the pixel electrodes PXE1, PXE2, and PXE3. The first connection electrode BE1 may be connected to the pixel electrodes PXE1, PXE2, and PXE3 through a first connection hole BH1 penetrating the organic layer 210 and the sacrificial electrode SFC. For example, the first connection electrode BE1 may contact the first reflective electrode SRF1 exposed through the first connection hole BH1. When the first reflective electrode SRF1 is omitted, the first connection electrode BE1 may directly contact the pixel electrodes PXE1, PXE2, and PXE3 through the first connection hole BH1. Further, the first connection electrode BE1 may be located on the top surface of the organic layer 210 and the first contact electrode CTE1.

The first connection electrode BE1 may include any one of molybdenum (Mo), aluminum (Al), chromium (Cr), gold (Au), titanium (Ti), nickel (Ni), neodymium (Nd), or copper (Cu). Alternatively, the first connection electrode BE1 may be made of a transparent conductive material (TCO), such as indium tin oxide (ITO) and indium zinc oxide (IZO).

The second connection electrode BE2 connects the second contact electrode CTE2 of the light-emitting element LE and the common electrodes CE1, CE2, and CE3. The second connection electrode BE2 may be connected to the common electrodes CE1, CE2, and CE3 through a second connection hole BH2 penetrating the organic layer 210 and the second sacrificial electrode SFC2. For example, the second connection electrode BE2 may contact the second reflective electrode SRF2 exposed through the second connection hole BH2. When the second reflective electrode SRF2 is omitted, the second connection electrode BE2 may directly contact the common electrodes CE1, CE2, and CE3 through the second connection hole BH2. Further, the second connection electrode BE2 may be located on the top surface of the organic layer 210 and the second contact electrode CTE2.

As shown in FIG. 7, the first connection hole BH1 and the second connection hole BH2 may gradually widen in diameter in an upward direction. In cross-section, the first connection hole BH1 and the second connection hole BH2 may have a sloped surface extending in a substantially straight line from the top surface to the bottom surface of the connection holes BH1 and BH2. The sloped surface that continues in a straight line means that the change in diameter is constant.

In addition, the first connection hole BH1 and the second connection hole BH2 may have a stepped structure whose diameter gradually becomes wider upward in cross section, as shown in FIG. 8. The diameter change value at the interface between the sacrificial electrodes SFC1 and SFC2 and the organic layer 210 may change significantly. As used herein, “in cross section” is defined as viewed in the first direction DR1 or is the second direction DR2. As used herein, “in a plane,” or “in plan view” is set based on a plane parallel to the plane defined by the first direction DR1 and the second direction DR2.

A portion of the top surface of the sacrificial electrodes SFC1 and SFC2 may be exposed in the first and second connection holes BH1 and BH2, which have a stepped structure whose diameter gradually becomes wider upward.

In a plane view, the sacrificial electrodes SFC1 and SFC2 in the first connection hole BH1 and the second connection hole BH2 surround the reflective electrodes SRF1 and SRF2 at the top of the reflective electrodes SRF1 and SRF2, which is the bottom. Therefore, in a plane, the first connection hole BH1 and the second connection hole BH2 form a stepping portion on which the respective top surfaces of the reflective electrodes SRF1 and SRF2, the sacrificial electrodes SFC1 and SFC2, and the organic layer 210 lie horizontally at each step of the staircase structure.

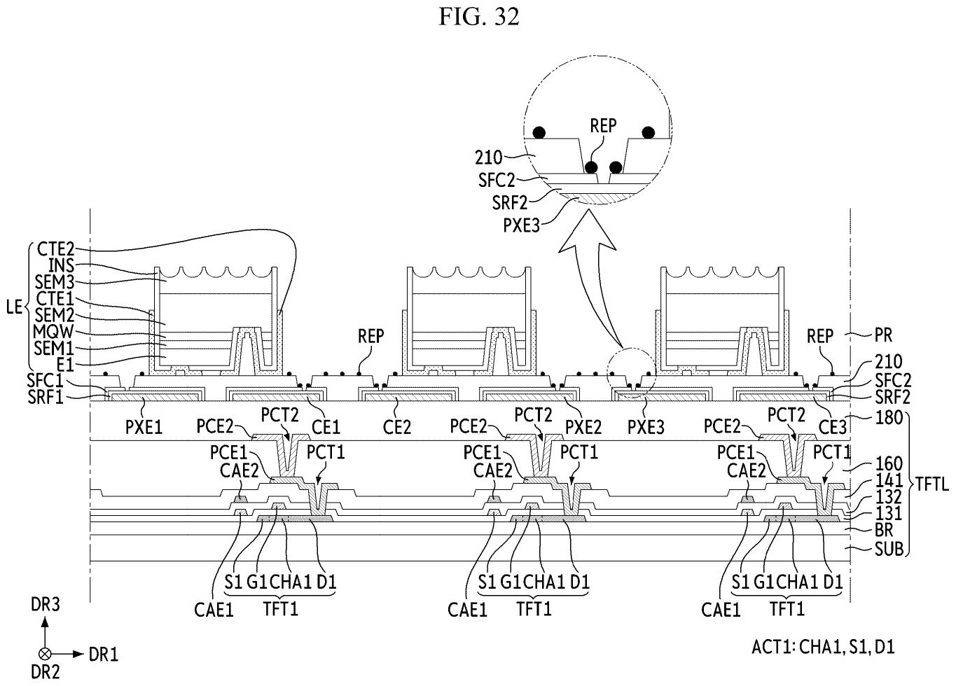

As can be seen with reference to FIG. 32, which will be described later, residual particles REP may remain not only on the top surface of the organic layer 210, but also on the top surfaces of the sacrificial electrodes SFC1 and SFC2 exposed by the first connection hole BH1 and the second connection hole BH2. On the other hand, no residual particles REP remain on the bottom surfaces of the first connection hole BH1 and the second connection hole BH2.

The connection of the connection electrodes BE1 and BE2 to the sacrificial electrodes SFC1 and SFC2 inside the connection hole BH1 is strengthened in that the area where the connection electrodes BE1 and BE2 may contact the sacrificial electrodes SFC1 and SFC2 is widened, thereby improving the reliability of the panel by forming the first connection hole BH1 and the second connection hole BH2 with a stepped structure whose diameter gradually becomes wider upward.

In addition, by forming the first connection hole BH1 and the second connection hole BH2 with a stepped structure whose diameter gradually becomes wider as it goes upward, the possibility of undercut formation at the boundary between the organic layer 210 and the sacrificial electrodes SFC1 and SFC2 may be reduced. As a result, the possibility of cracks occurring at the boundary between the organic layer 210 and the sacrificial electrodes SFC1 and SFC2 when forming the connection electrodes BE1 and BE2 may be reduced, thereby improving the reliability of the panel.

The thickness of the first connection electrode BE1 and the second connection electrode BE2 may each be about 1000 Å but is not limited thereto.

The second connection electrode BE2 may include any one of molybdenum (Mo), aluminum (Al), chromium (Cr), gold (Au), titanium (Ti), nickel (Ni), neodymium (Nd), or copper (Cu). Alternatively, the second connection electrode BE2 may be made of a transparent conductive material (TCO), such as indium tin oxide (ITO) and indium zinc oxide (IZO).

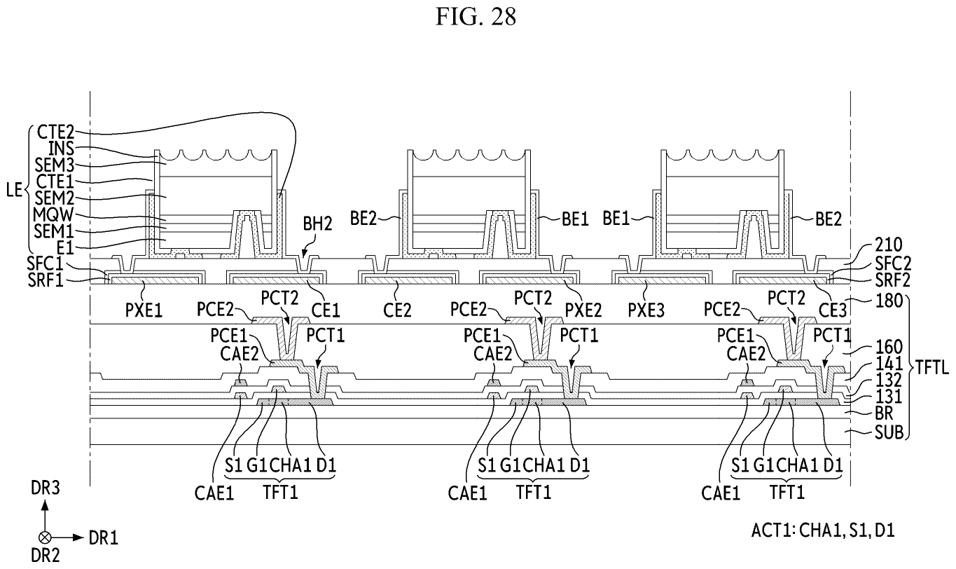

In one or more embodiments, the first connection electrode BE1 and the second connection electrode BE2 may be formed of the same material as the sacrificial electrodes SFC1 and SFC2, for example, indium zinc oxide (IZO). When the first connection electrode BE1 and the second connection electrode BE2 are made of the same material, there may be an advantage in terms of process. The advantages of the process will be described in detail with reference to FIG. 28.

The second organic film 211 may cover a portion of the side surfaces of the plurality of light-emitting elements LE. Further, the second organic film 211 may cover the first connection electrode BE1 and the second connection electrode BE2.

A third organic film 212 may be located on a second organic film 211. The third organic film 212 may cover another portion of the side surface of each of the plurality of light-emitting elements LE. The third organic film 212 may be located on the protective layer INS, the first connection electrode BE1, and the second connection electrode BE2 that are not covered by the second organic film 211, as shown in FIG. 7. However, the embodiments of the present disclosure are not limited thereto. The top surface of each of the plurality of light-emitting elements LE may be exposed without being covered by the third organic film 212.

The second organic film 211 and the third organic film 212 are layers for flattening steps caused by the plurality of light-emitting elements LE. When the height of the second organic film 211 is arranged to cover most of the side surfaces of each of the plurality of light-emitting elements LE, the third organic film 212 may be omitted.

The second organic film 211 and the third organic film 212 may be formed from an organic film, such as an acrylic resin, an epoxy resin, a phenolic resin, a polyamide resin, a polyimide resin, or the like.

A first capping layer CAP1 may be located on the third organic film 212 and the light-emitting element LE.

A light-blocking layer BM, a first light conversion layer QDL1, a second light conversion layer QDL2, and a light transmission layer TPL may be located on the first capping layer CAP1. The first light conversion layer QDL1, the second light conversion layer QDL2, and the light transmission layer TPL may be formed by the compartments the light-blocking layer BM. Therefore, the first light conversion layer QDL1 may be located on the first capping layer CAP1 in the first sub-pixel SPX1, the second light conversion layer QDL2 may be located on the first capping layer CAP1 in the second sub-pixel SPX2, and the light transmission layer TPL may be located on the first capping layer CAP1 in the third sub-pixel SPX3. The light-blocking layer BM may not overlap the plurality of light-emitting elements LE in the third direction DR3.

The first light conversion layer QDL1 may convert a portion of the third light (light in the blue wavelength band) incident from the light-emitting element LE into first light (light in the red wavelength band). The first light conversion layer QDL1 may include a first base resin BRS1 and a first wavelength conversion particle WCP1. The first base resin BRS1 may include a light-transmitting organic material. The first wavelength conversion particle WCP1 may convert a portion of the third light (light in the blue wavelength band) incident from the light-emitting element LE into first light (light in the red wavelength band).

The second light conversion layer QDL2 may convert a portion of the third light (light in the blue wavelength band) incident from the light-emitting element LE into second light (light in the green wavelength band). The second light conversion layer QDL2 may include a second base resin BRS2 and a second wavelength conversion particle WCP2. The second base resin BRS2 may include a light-transmitting organic material. The second wavelength conversion particle WCP2 may convert a portion of the third light (light in the blue wavelength band) incident from the light-emitting element LE into second light (light in the green wavelength band).

The light transmission layer TPL may include a light-transmitting organic material.

For example, the first base resin BRS1, the second base resin BRS2, and the light transmission layer TPL may include an epoxy-based resin, an acrylic-based resin, a cardo-based resin, or an imide-based resin. The first and second wavelength conversion particles WCP1 and WCP2 may be quantum dots (QD), quantum rods, fluorescent materials, or phosphorescent materials.

The light-blocking layer BM may include a first light-blocking layer BM1 and a second light-blocking layer BM2 that are sequentially stacked. A length of the first light-blocking layer BM1 in the first direction DR1 or a length of the second direction DR2 may be wider than a length of the second light-blocking layer BM2 in the first direction DR1 or a length of the second direction DR2 of the second light-receiving layer BM2. The first light-blocking layer BM1 and the second light-blocking layer BM2 may be formed of an organic film, such as an acrylic resin, an epoxy resin, a phenolic resin, a polyamide resin, a polyimide resin, or the like. The first light-blocking layer BM1 and the second light-blocking layer BM2 may include a light-blocking material to reduce or prevent light from the light-emitting element LE of one sub-pixel from proceeding to the neighboring sub-pixel. For example, the first light-blocking layer BM1 and the second light-blocking layer BM2 may include an inorganic black pigment, such as carbon black or an organic black pigment.

The second capping layer CAP2 may be located on the first capping layer CAP1 and the light-blocking layer BM. The second capping layer CAP2 may be located on the side and top surfaces of the light-blocking layer BM. That is, the second capping layer CAP2 may be located on the side of the first light-blocking layer BM1 and the side and top surfaces of the second light-blocking layer BM2.

The reflective film RF may be located between the light-blocking layer BM and the first light conversion layer QDL1, between the light-blocking layer BM and the second light conversion layer QDL2, and between the light-blocking layer BM and the light transmission layer TPL. The reflective film RF may be located on a second capture layer CAP2 located on the side of the first light-blocking layer BM1 and the side of the second light-blocking layer BM2. The reflective film RF serves to reflect light traveling in the lateral direction from the first light conversion layer QDL1, the second light conversion layer QDL2, and the light transmission layer TPL.

The reflective film RF may include a highly reflective metal material, such as aluminum (Al). The thickness of the reflective film RF may be approximately 0.1 μm.

Alternatively, the reflective layer RF may include a first layer and a second layer of M (M is an integer of 2 or more) pairs having different refractive indices to serve as Distributed Bragg Reflectors (DBR). In this case, M first layers and M second layers may be arranged alternately. The first layer and the second layer may be formed of an inorganic film, for example, silicon nitride (SiNₓ), silicon oxide (SiON), silicon oxide (SiOₓ), titanium oxide (TiOₓ), or aluminum oxide (AlOₓ).

The third capping layer CAP3 may be located on the second capping layer CAP2, the first light conversion layer QDL1, the second light conversion layer QDL2, and the light transmission layer TPL.

The first capping layer CAP1, the second capping layer CAP2, and the third capping layer CAP3 may be formed of an inorganic film, for example, silicon nitride (SiNₓ), silicon oxide (SiON), silicon oxide (SiOₓ), titanium oxide (TiOₓ), or aluminum oxide (AlOₓ). The first light conversion layer QDL1, the second light conversion layer QDL2, and the light transmission layer TPL may be encapsulated by the first capture layer CAP1, the second capping layer CAP2, and the third capping layer CAP3.

A fourth organic film 213 may be located on the second capping layer CAP2. A plurality of color filters CF1, CF2, and CF3 may be located on the fourth organic film 213. The plurality of color filters CF1, CF2, and CF3 may include first color filters CF1, second color filters CF2, and third color filters CF3.

The first color filter CF1 located in the first sub-pixel SPX1 may transmit the first light (light in the red wavelength band), and may absorb, reduce, or block the third light (light in the blue wavelength band). Therefore, the first color filter CF1 may transmit the first light (light in the red wavelength band) that has been converted by the first light conversion layer QDL1 among the third light (light in the blue wavelength band) emitted from the light-emitting element LE, and may absorb, reduce, or block the third light (light in the blue wavelength band) that has not been converted by the first light conversion layer QDL1. Accordingly, the first sub-pixel SPX1 may emit the first light (light in the red wavelength band).

The second color filter CF2 located in the second sub-pixel SPX2 may transmit the second light (light in the green wavelength band), and may absorb, reduce, or block the third light (light in the blue wavelength band). Therefore, the second color filter CF2 may transmit the second light (light in the green wavelength band) that has been converted by the first light conversion layer QDL1 among the third light (light in the blue wavelength band) emitted from the light-emitting element LE and absorb, reduce, or block the third light (light in the blue wavelength band) that has not been converted by the first light conversion layer QDL1. Accordingly, the second sub-pixel SPX2 may emit the second light (light in the green wavelength band).

The third color filter CF3 located in the third sub-pixel SPX3 may transmit the third light (light in the blue wavelength band). Therefore, the third color filter CF3 may transmit the third light (light in the blue wavelength band) emitted from the light-emitting element LE passing through the light transmission layer TPL. Accordingly, the third sub-pixel SPX3 may emit the third light (light in the blue wavelength band).

The first color filter CF1, the second color filter CF2, and the third color filter CF3 overlapping in the third direction DR3 may overlap with the light-blocking layer BM in the third direction DR3.

A fifth organic film 214 may be located on the plurality of color filters CF1, CF2, and CF3 for planarization.

The fourth organic film 213 and the fifth organic film 214 may be formed from an acrylic resin, an epoxy resin, a phenolic resin, a polyamide resin, a polyimide resin, or the like.

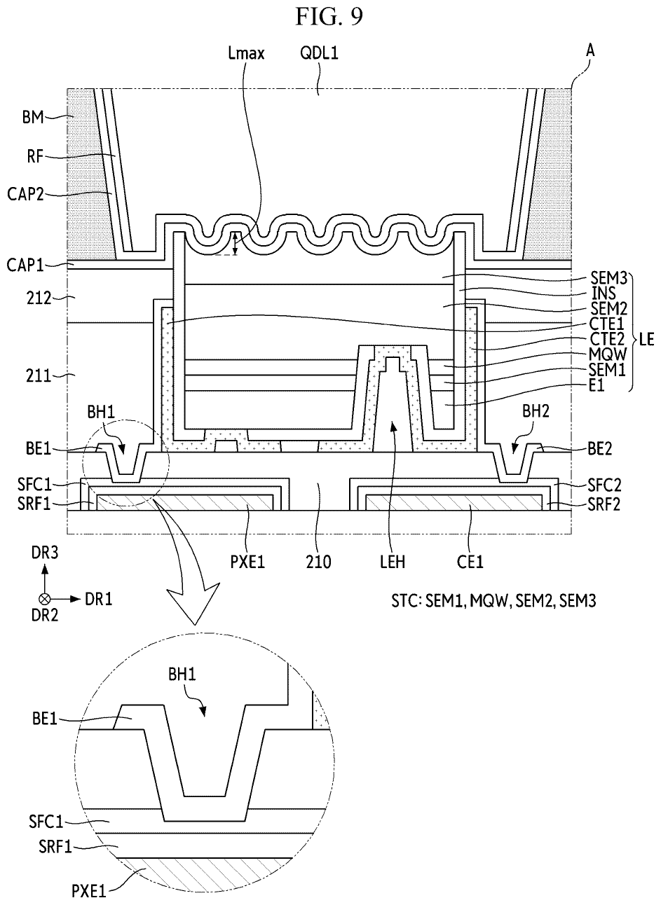

FIG. 9 is a cross-sectional view illustrating another example of area A of FIG. 6 in detail.

The one or more embodiments corresponding to FIG. 9 are different from the one or more embodiments corresponding to FIG. 7 in that the connection holes BH1 and BH2 penetrate the organic layer 210, but do not penetrate the sacrificial electrodes SFC1, SFC2. In the one or more embodiments corresponding to FIG. 9, descriptions overlapping with the one or more embodiments corresponding to FIG. 7 will not be repeated, and the description will focus on differences from the one or more embodiments corresponding to FIG. 7.

Referring to FIG. 9, the sacrificial electrodes SFC1 and SFC2 may have different thicknesses in the area overlapping the connection holes BH1 and BH2 and in other areas. The upper portion of the sacrificial electrodes SFC1 and SFC2 may be removed, and the lower portion may remain in the area overlapping the connection holes BH1 and BH2. Accordingly, the connection holes BH1 and BH2 may expose the sacrificial electrodes SFC1 and SFC2.

The first connection hole BH1 penetrates the organic layer 210, and may be defined by a downward concave groove on the first sacrificial electrode SFC1, and the second connection hole BH2 penetrates the organic layer 210 and may be defined by a downward concave groove on the second sacrificial electrode SFC2.

The first connection electrode BE1 connects the first contact electrode CTE1 of the light-emitting element LE and the pixel electrodes PXE1, PXE2, and PXE3. The first connection electrode BE1 may contact the first sacrificial electrode SFC1 exposed through the first connection hole BH1.

The second connection electrode BE2 connects the second contact electrode CTE2 of the light-emitting element LE and the common electrodes CE1, CE2, and CE3. The second connection electrode BE2 may contact the second sacrificial electrode SFC2 exposed through the second connection hole BH2.

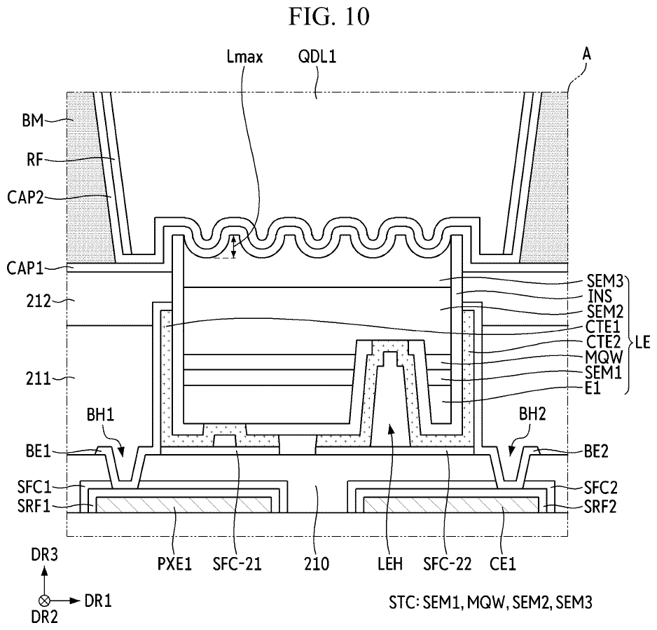

FIG. 10 is a cross-sectional view illustrating another example of area A of FIG. 6 in detail.

The one or more embodiments corresponding to FIG. 10 are different from the one or more embodiments corresponding to FIG. 7 in that they further include sacrificial electrodes SFC-21 and SFC-22 between the contact electrodes CTE1 and CTE2 and the organic layer 210. In the one or more embodiments corresponding to FIG. 10, descriptions overlapping with the one or more embodiments corresponding to FIG. 7 will not be repeated, and the description will focus on differences from the one or more embodiments corresponding to FIG. 7.

The sacrificial electrodes SFC-21 and SFC-22 are referred to as element sacrificial electrodes SFC-21 and SFC-22 to clearly distinguish them from the sacrificial electrodes SFC1 and SFC2 located between the connection electrodes BE1 and BE2.

A first element sacrificial electrode SFC-21 may be located between the first contact electrode CTE1 and the organic layer 210, and a second element sacrificial electrode SFC-22 may be located between the second contact electrode CTE2 and the organic layer 210. The first element sacrificial electrode SFC-21 and the second element sacrificial electrode SFC-22 may completely overlap one surface of the light-emitting element LE. The element sacrificial electrodes SFC-21 and SFC-22 may be formed of a conductive metal.

In one or more embodiments, the reflective electrode SRF may be formed from a multilayer of ITO/Aluminum (Al)/ITO, and the sacrificial electrode SFC and the element sacrificial electrodes SFC-21 and SFC-22 may be formed from IZO.

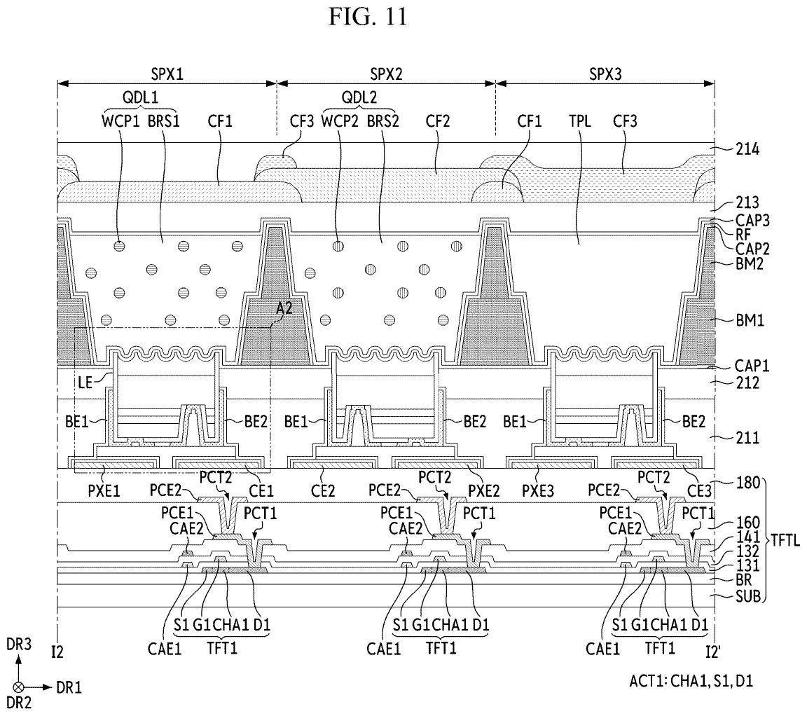

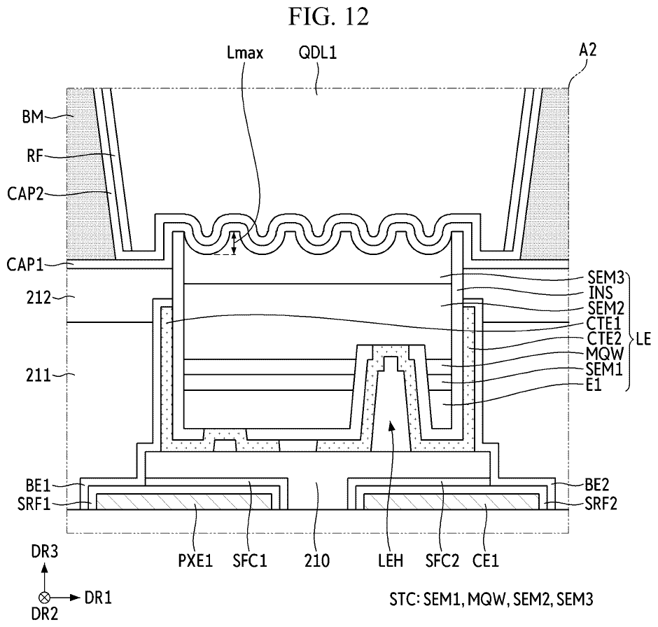

FIG. 11 is a cross-sectional view illustrating another example of a cross-section of the display panel taken along the line I-I′ in FIG. 5. FIG. 12 is a cross-sectional view illustrating area A2 in FIG. 11 in detail.

The embodiments of FIGS. 11 and 12 differ from the embodiments of FIGS. 6 and 7 in that each of the organic layers 210 is located on a portion of the top surface of the pixel electrodes PXE1, PXE2, and PXE3 and a portion of the top surface of the common electrode CE, and the sacrificial electrodes SFC1 and SFC2 are located only in areas where they contact (and overlap) with the organic layers 210. In FIGS. 11 and 12, descriptions overlapping with the embodiments of FIGS. 6 and 7 will be omitted, and the description will focus on differences from the embodiments of FIGS. 6 and 7.

Referring to FIGS. 11 and 12, because each of the organic layers 210 is located on a portion of the top surface of each of the pixel electrodes PXE1, PXE2, and PXE3 and a portion of each of the common electrodes CE1, CE2, and CE3, it is not necessary to form a first connection hole BH1 to expose the first reflective electrode SRF1 or to form a second connection hole BH2 to expose the second reflective electrode SRF2.

Each of the first connection electrodes BE1 may be located on the top surface of the first reflective electrode SRF1 that is not covered by the organic layer 210. Each of the second connection electrodes BE2 may be located on the top surface of the second reflective electrode SRF2 that is not covered by the organic layer 210. Further, each of the first connection electrode BE1 and the second connection electrode BE2 may be located on the top surface and at least one side of the organic layer 210.

The first sacrificial electrode SFC1 may be located between the first reflective electrode SRF1 and the organic layer 210, and may expose at least a portion of the first reflective electrode SRF1. For example, the first sacrificial electrode SFC1 may be located only in an area that overlaps the organic layer 210.

The second sacrificial electrode SFC2 may be located between the second reflective electrode SRF2 and the organic layer 210, and may expose at least a portion of the second reflective electrode SRF2. For example, the second sacrificial electrode SFC2 may be located only in an area that overlaps the organic layer 210.

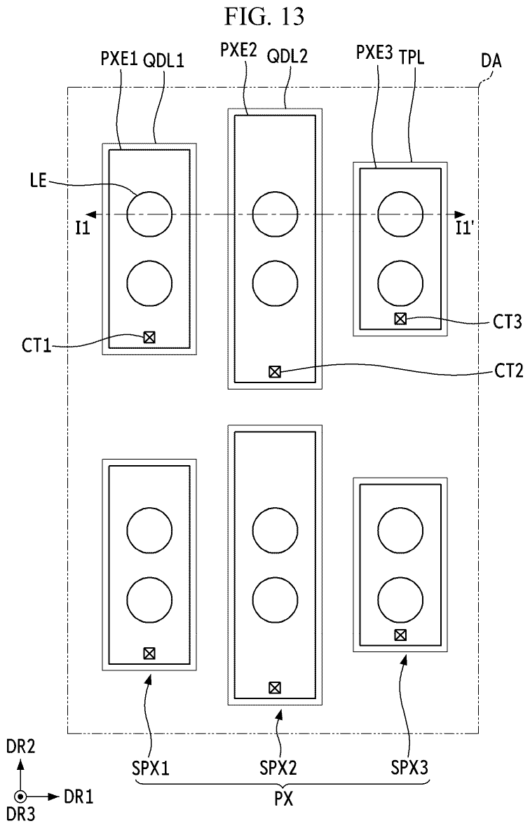

FIG. 13 is a layout diagram illustrating pixels of a display area according to one or more embodiments.

The one or more embodiments corresponding to FIG. 13 differs from the one or more embodiments corresponding to FIG. 5 in that the light-emitting element LE overlaps the pixel electrodes PXE1, PXE2, and PXE3 in each of the first sub-pixel SPX1, the second sub-pixel SPX2, and the third sub-pixel SPX3. In the one or more embodiments corresponding to FIG. 13, descriptions overlapping with the one or more embodiments corresponding to FIG. 5 will be omitted.

Referring to FIG. 13, the first sub-pixel SPX1 includes a first pixel electrode PXE1, a plurality of light-emitting elements LE, and a first light conversion layer QDL1. The second sub-pixel SPX2 includes a second pixel electrode PXE2, a plurality of light-emitting elements LE, and a second light conversion layer QDL2. The third sub-pixel SPX3 includes a third pixel electrode PXE3, a plurality of light-emitting elements LE, and a light transmission layer (or third light conversion layer) TPL.

Each of the first pixel electrode PXE1, the second pixel electrode PXE2, and the third pixel electrode PXE3 may have a rectangular planar shape with a short side in the first direction DR1 and a long side in the second direction DR2. Depending on the light conversion efficiency of the first light conversion layer QDL1 and the light conversion efficiency of the second light conversion layer QDL2, an area of the first sub-pixel SPX1, an area of the second sub-pixel SPX2, and an area of the third sub-pixel SPX3 may be set. For example, the lower the light conversion efficiency, the larger the area of the sub-pixel.

For example, as shown in FIG. 13, when the light conversion efficiency of the second light conversion layer QDL2 is lower than the light conversion efficiency of the first light conversion layer QDL1, the area of the second subpixel electrode PXE2 may be larger than the area of the first subpixel electrode PXE1. Furthermore, the area of the first pixel electrode PXE1 may be larger than the area of the third pixel electrode PXE3 because the light transmission layer TPL transmits light from the light-emitting element LE as it is, whereas the first light conversion layer QDL1 converts the light.

Each of the pixel electrodes PXE1, PXE2, and PXE3 may be electrically connected to at least one transistor through the pixel connection hole CT1, CT2, and CT3. For example, each of the pixel electrodes PXE1, PXE2, and PXE3 may be electrically connected to the second electrode of the fourth transistor (ST4 in FIG. 4) and the second electrode of the sixth transistor (ST6 in FIG. 4) of the corresponding sub-pixel.

A plurality of light-emitting elements LE may be located on each of the pixel electrodes PXE1, PXE2, and PXE3. The same number of light-emitting elements LE may be located on each of the pixel electrodes PXE1, PXE2, and PXE3. For example, two light-emitting elements LE may be located on each of the pixel electrodes PXE1, PXE2, and PXE3.

The first light conversion layer QDL1 may completely overlap the first pixel electrode PXE1 and the plurality of light-emitting elements LE of the first sub-pixel SPX1. The area of the first light conversion layer QDL1 may be larger than the area of the first pixel electrode PXE1. The first light conversion layer QDL1 may convert or shift the peak wavelength of incident light into light of another corresponding peak wavelength and emit it. For example, the first light conversion layer QDL1 may convert or shift the third light emitted from the plurality of light-emitting elements LE of the first sub-pixel SPX1 into first light.

The second light conversion layer QDL2 may completely overlap the plurality of light-emitting elements LE of the second pixel electrode PXE2 and the second sub-pixel SPX2. The area of the second light conversion layer QDL2 may be larger than the area of the second pixel electrode PXE2. The second light conversion layer QDL2 may convert or shift the peak wavelength of incident light into light of another corresponding peak wavelength and emit it. For example, the second light conversion layer QDL2 may convert or shift the third light emitted from the plurality of light-emitting elements LE of the second sub-pixel SPX2 into second light.

The light transmission layer TPL may completely overlap the plurality of light-emitting elements LE of the third pixel electrode PXE3 and the third sub-pixel SPX3. The light transmission layer TPL may transmit incident light as it is. For example, the light transmission layer TPL may directly transmit the third light emitted from the plurality of light-emitting elements LE of the third sub-pixel SPX3.

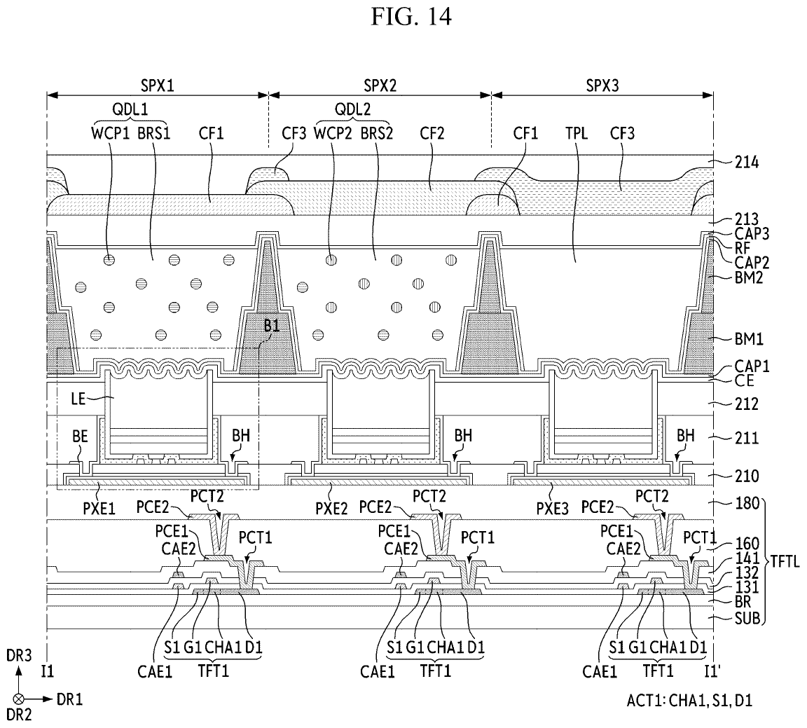

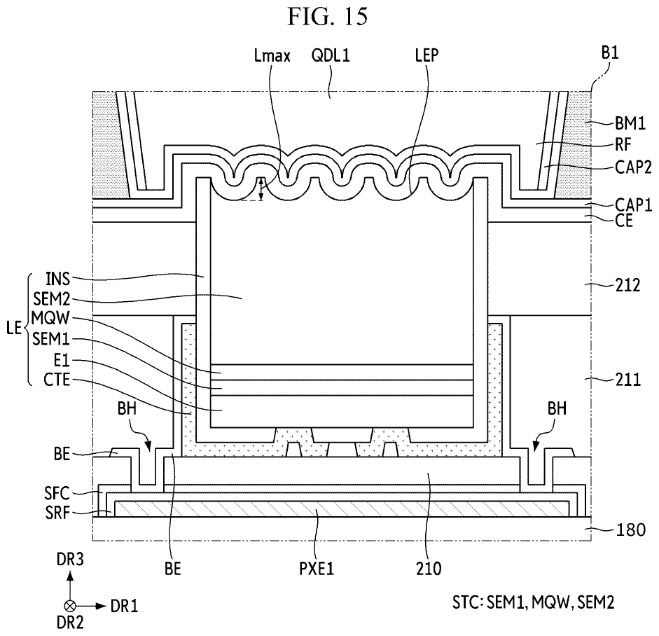

FIG. 14 is a cross-sectional view illustrating a cross-section of a display panel taken along the line I1-I1′ in FIG. 13. FIG. 15 is a cross-sectional view illustrating area B1 in FIG. 14 in detail.

The embodiments of FIGS. 14 and 15 differ from the embodiments of FIGS. 6 and 7 in that the light-emitting element LE is a vertical type micro LED in which each of the plurality of light-emitting elements LE extends in the third direction DR3. A vertical micro LED refers to an LED having a structure in which a first semiconductor layer SEM1, an active layer MQW, and a second semiconductor layer SEM2 are sequentially arranged in the vertical third direction DR3. Each of the plurality of light-emitting elements LE may include a substantially vertical side surface. The light-emitting element LE may be patterned through vertical etching and may have a rectangular or square cross-sectional shape where a width of the top surface and a width of the bottom surface are substantially equal.

In the embodiments of FIGS. 14 and 15, descriptions overlapping with those of the embodiments of FIGS. 6 and 7 will be omitted.

Referring to FIGS. 14 and 15, a pixel electrode layer may be located on the second planarization organic film 180. The pixel electrode layer may include a first pixel electrode PXE1, a second pixel electrode PXE2, and a third pixel electrode PXE3.

A reflective electrode SRF may be located on each of the pixel electrodes PXE1, PXE2, and PXE3. The reflective electrode SRF may be formed as a single layer of a highly reflective metal, or may be formed as a multilayer, such as titanium (Ti)/aluminum (Al)/titanium (Ti) or ITO/aluminum (Al)/ITO.

A sacrificial electrode SFC may be located on the reflective electrode SRF. The sacrificial electrode SFC may be formed of a conductive metal.

In one or more embodiments, the reflective electrode SRF may be formed from a multilayer of ITO/Aluminum (Al)/ITO, and the sacrificial electrode (SFC) may be formed from IZO.

The plurality of light-emitting elements LE may be located on the organic layer 210.

Each of the plurality of light-emitting elements LE may have a length of several to hundreds of μm in the first direction DR1, a length in the second direction DR2, and a length in the third direction DR3. For example, each of the plurality of light-emitting elements LE may have a length in the first direction DR1, a length in the second direction DR2, and a length in the third direction DR3 of approximately 100 μm or less.

The light-emitting element LE may include a conductive layer E1, a semiconductor stack STC, a contact electrode CTE, and a protective film INS. The semiconductor stack STC may include a first semiconductor layer SEM1, an active layer MQW, a second semiconductor layer SEM2, and a third semiconductor layer SEM3 sequentially arranged in the third direction DR3.

The protective film INS may be located on a side of the first semiconductor layer SEM1, the side of the active layer MQW, the side of the second semiconductor layer SEM2, and the third semiconductor layer SEM3. The protective film INS may be a film to protect the side surface of the light-emitting element LE. The protective film INS may be formed of an inorganic film, for example, silicon nitride (SiNₓ), silicon oxide (SiON), silicon oxide (SiOₓ), titanium oxide (TiOₓ), or aluminum oxide (AlOₓ).

The plurality of contact electrodes CTE may be located on the protective film INS. Each of the plurality of contact electrodes CTE may be located between the organic layer 210 and the protective layer INS. Each of the plurality of contact electrodes CTE may be in contact with the organic layer 210.

Each of the plurality of contact electrodes CTE may be connected to the exposed conductive layer E1 that is not covered by the protective film INS. As a result, even if one of the plurality of contact electrodes CTE is not connected to the conductive layer E1 due to a process error, the other contact electrode CTE is connected to the conductive layer E1, thereby reducing or preventing the likelihood of the light-emitting element LE failing to light up.

When the plurality of contact electrodes CTE are formed of a metal with high reflectivity, light emitted from the active layer MQW of the light-emitting element LE may be reflected by the plurality of contact electrodes CTE to be emitted to the top surface of the light-emitting element LE, among the light emitted from the active layer MQW of the light-emitting element LE in the lateral direction of the light-emitting element LE. Therefore, because light loss from the light-emitting element LE may be reduced, the light efficiency of the light-emitting element LE may be increased. Accordingly, it is suitable that each of the plurality of contact electrodes CTE is arranged to cover most of the side surface of the semiconductor stack STC to increase the light efficiency of the light-emitting element LE.

The plurality of contact electrodes CTE may include any one of molybdenum (Mo), aluminum (Al), chromium (Cr), gold (Au), titanium (Ti), nickel (Ni), neodymium (Nd), or copper (Cu). For example, the plurality of contact electrodes CTE may be formed as a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO) to increase reflectivity.

Each of the plurality of contact electrodes CTE may be located on a side of the semiconductor stack STC. Among the side surfaces of the semiconductor stack STC, an area adjacent to the top surface of the semiconductor stack STC may be covered by the protective film INS, but may be exposed without being covered by the plurality of contact electrodes CTE.

The connection electrode BE connects the contact electrode CTE of the light-emitting element LE to the pixel electrodes PXE1, PXE2, and PXE3. The connection electrode BE may be in contact with the exposed reflective electrode SRF through the connection hole BH penetrating the organic layer 210 and the sacrificial electrode SFC. Additionally, the connection electrode BE may be located on the top surface of the organic layer 210 and the contact electrode CTE. In one or more other embodiments, the connection hole BH may not penetrate all the sacrificial electrode SFC, and only the top of the sacrificial electrode SFC may be removed and exposed. In this case, the connection electrode BE may contact the sacrificial electrode SFC exposed by the connection hole BH.

The connection electrode BE may include any one of molybdenum (Mo), aluminum (Al), chromium (Cr), gold (Au), titanium (Ti), nickel (Ni), neodymium (Nd), or copper (Cu). Alternatively, the connection electrode BE may be made of a transparent conductive material (TCO), such as indium tin oxide (ITO) and indium zinc oxide (IZO).

The connection electrode BE may be located on a side of the semiconductor stack STC. Among the side surfaces of the semiconductor stack STC, an area adjacent to the top surface of the semiconductor stack STC may be exposed without being covered by the connection electrode BE. For example, the separation distance between the top surface of the semiconductor stack STC and the connection electrode BE in the third direction DR3 may be greater than approximately 100 nm. Further, the separation distance between the top surface of the semiconductor stack STC and the connection electrode BE in the third direction DR3 may be greater than the maximum length Lmax of the light extraction pattern in the third direction DR3.

The separation distance between the top surface of the semiconductor stack STC and the connection electrode BE in the third direction DR3 may be greater than the separation distance between the top surface of the semiconductor stack STC and the contact electrode CTE in the third direction DR3, but embodiments of the present disclosure are not limited thereto. In one example, the separation distance between the top surface of the semiconductor stack STC and the connection electrode BE in the third direction DR3 may be less than the separation distance between the top surface of the semiconductor stack STC and the contact electrode CTE in the third direction DR3. In this case, the connection electrode BE may cover at least a portion of the exposed protective film INS without being covered by the contact electrode CTE. Alternatively, the connection electrode BE may cover the entire exposed protective film INS without being covered by the contact electrode CTE. As another example, the separation distance between the top surface of the semiconductor stack STC and the connection electrode BE in the third direction DR3 may be substantially the same as the separation distance between the top surface of the semiconductor stack STC and the contact electrode CTE in the third direction DR3.

The second organic film 211 may cover a portion of the side surfaces of the plurality of light-emitting elements LE. Further, the second organic film 211 may cover the connection electrode BE.

The third organic film 212 may be located on the second organic film 211. The third organic film 212 may cover another portion of the side surface of each of the plurality of light-emitting elements LE. The third organic film 212 may be located on the protective layer INS, the contact electrode CTE, and the connection electrode BE that are exposed and not covered by the second organic film 211, as shown in FIG. 7, but embodiments of the present disclosure are not limited thereto. In one example, the entire connection electrode BE may be covered by the second organic film 211. The top surface of each of the plurality of light-emitting elements LE may be exposed without being covered by the third organic film 212.

The second organic film 211 and the third organic film 212 are layers for flattening steps caused by the plurality of light-emitting elements LE. When the height of the second organic film 211 is arranged to cover most of the side surfaces of each of the plurality of light-emitting elements LE, the third organic film 212 may be omitted.

The second organic film 211 and the third organic film 212 may be formed from an organic film, such as an acrylic resin, an epoxy resin, a phenolic resin, a polyamide resin, a polyimide resin, or the like.

The common electrode CE may be located on the top surface of each of the plurality of light-emitting elements LE and the third organic film 212. The common electrode CE may be a common layer commonly formed in the first sub-pixel SPX1, the second sub-pixel SPX2, and the third sub-pixel SPX3. The common electrode CE may be made of a transparent conductive material (TCO), such as indium tin oxide (ITO) and indium zinc oxide (IZO), which may transmit light.

The pixel electrodes PXE1, PXE2, and PXE3 may be referred to as an anode electrode or a first electrode, and the common electrode CE may be referred to as a cathode electrode or a second electrode.

The first capping layer CAP1 may be located on the common electrode CE.

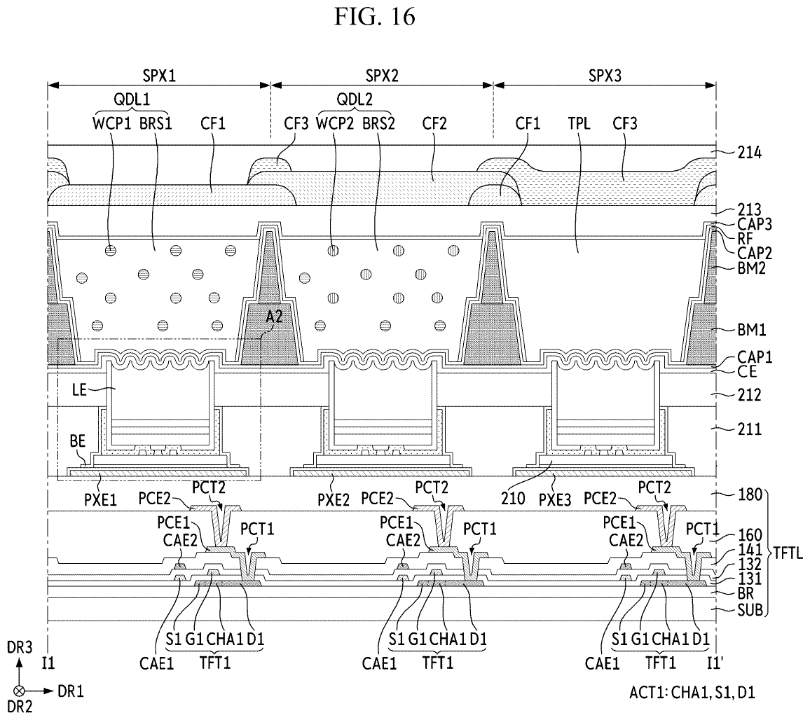

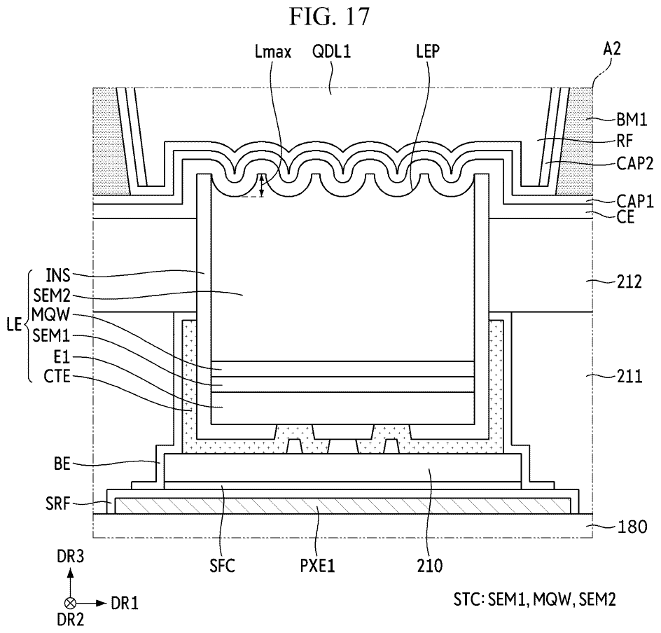

FIG. 16 is a cross-sectional view illustrating another example of a cross-section of the display panel taken along the line I1-I1′ in FIG. 13. FIG. 17 is a cross-sectional view illustrating another example of area A2 of FIG. 16.

The embodiments of FIGS. 16 and 17 differ from the embodiments of FIGS. 14 and 15 in that each of the organic layers 210 is located on a portion of the top surface of the pixel electrode PXE, and the sacrificial electrode SFC is located only in the area that contacts (and overlaps) the organic layer 210. In FIGS. 16 and 17, descriptions overlapping with the embodiments of FIGS. 14 and 15 will be omitted, and the description will focus on differences from the embodiments of FIGS. 14 and 15.

Referring to FIGS. 16 and 17, because each of the organic layers 210 is located on a portion of the top surface of the pixel electrode PXE, there is no need to form a connection hole BH to expose the reflective electrode SRF. The connection electrode BE may be located on the top surface of the reflective electrode SRF that is not covered by the organic layer 210. The connection electrode BE may be located on the top and side surfaces of the organic layer 210.

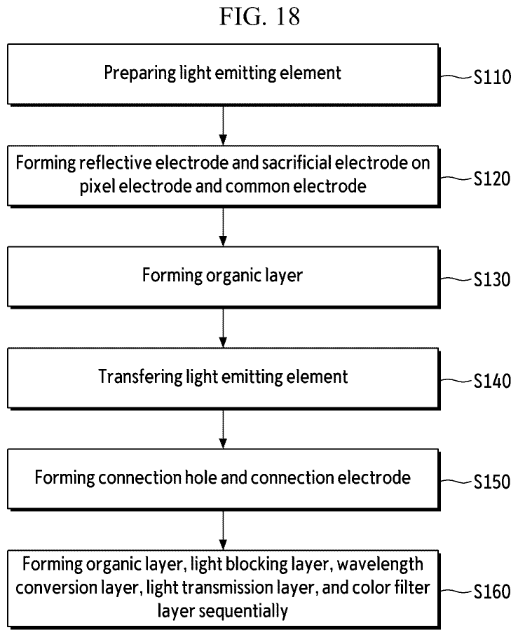

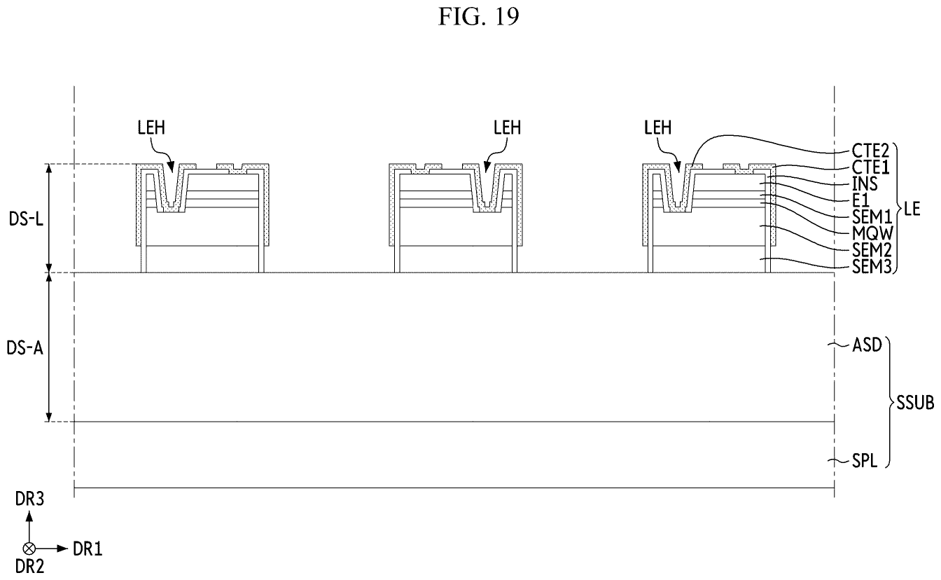

FIG. 18 is a flowchart illustrating a method of manufacturing a display device according to one or more embodiments. FIGS. 19 to 30 are diagrams to illustrate a method of manufacturing a display device according to one or more embodiments.

Hereinafter, FIG. 18 will be described in conjunction with FIGS. 19 to 30 to further describe a method of manufacturing a display device according to one or more embodiments. In FIGS. 19 to 30, cross-sections corresponding to line I-I′ of FIG. 6 are shown for convenience of explanation.

First, as shown in FIG. 19, a light-emitting element LE located on a first substrate SSUB may be prepared (S110 in FIG. 18).

The light-emitting element LE may be a device grown on a semiconductor substrate, and may be the light-emitting element LE described with reference to FIGS. 6 and 7.

The semiconductor substrate may be a silicon wafer substrate or a sapphire substrate. The light-emitting element LE grown on the semiconductor substrate may be transferred onto the substrate SUB of the display panel through one or more relay substrates.

A relay substrate SSUB may include a support layer SPL and an adhesive layer ASD. The support layer SPL may be made of a transparent, mechanically stable material that allows light to transmit through. For example, the support layer SPL may include a transparent polymer, such as polyester, polyacrylic, polyoxy, polyethylene, polystyrene, polyethylene terephthalate, or the like.

An adhesive layer ASD having adhesive force may be located on the support layer SPL.

The thickness DS-A of the adhesive layer ASD may be thicker than the height DS-L of the light-emitting element LE. For example, the thickness of the adhesive layer ASD may be about 50 μm.

The adhesive layer ASD may include an adhesive material for bonding the light-emitting element LE. For example, the adhesive material may be a siloxane-based organic polymer, such as an organosilicon compound, such as polydimethylsiloxane PDMS. The adhesive material may have fluidity.

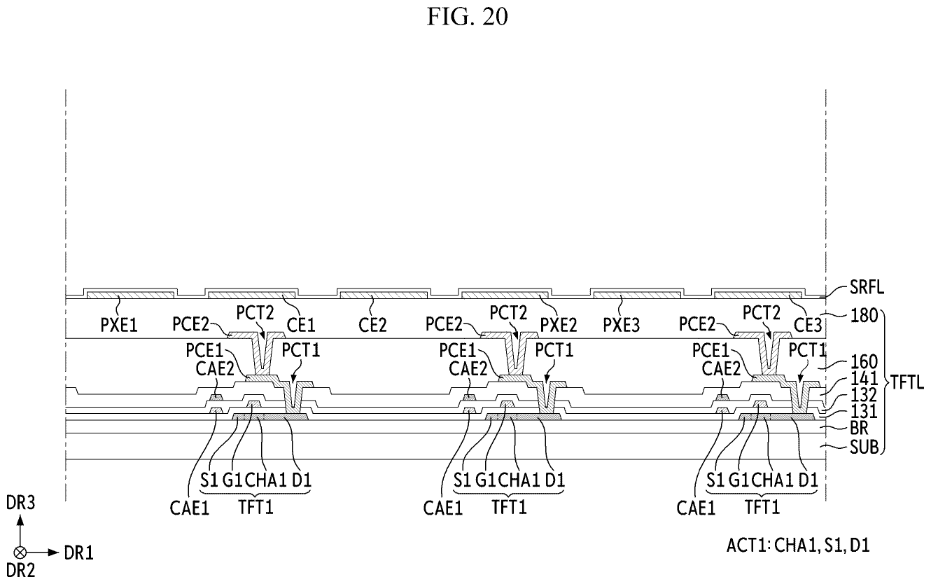

As shown in FIGS. 20 to 22, reflective electrodes SRF1 and SRF2 and sacrificial electrodes SFC1 and SFC2 are formed on the pixel electrodes PXE1, PXE2, and PXE3 and the common electrodes CE1, CE2, and CE3 (S120 in FIG. 18).

A reflective material layer SRFL and a sacrificial material layer SFCL may be sequentially deposited on the entire surface of the pixel electrodes PXE1, PXE2, and PXE3 and the common electrodes CE1, CE2, and CE3.

For example, referring to FIG. 20, the reflective material layer SRFL may be entirely deposited on one side of the substrate SUB. The reflective material layer SRFL may cover the pixel electrodes PXE1, PXE2, and PXE and the common electrodes CE1, CE2, and CE3. The reflective material layer SRFL may be formed on one surface of the semiconductor substrate SSUB exposed between the pixel electrodes PXE1, PXE2, and PXE3 and the common electrodes CE1, CE2, and CE3.

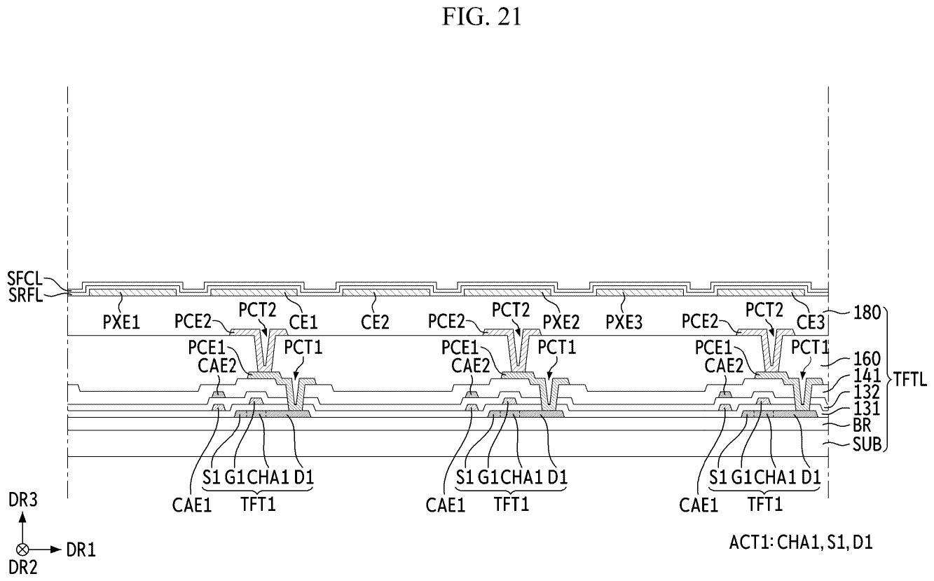

Then, referring to FIG. 21, a sacrificial material layer SFCL may be entirely deposited on one side of the substrate SUB to cover the reflective material layer SRFL.

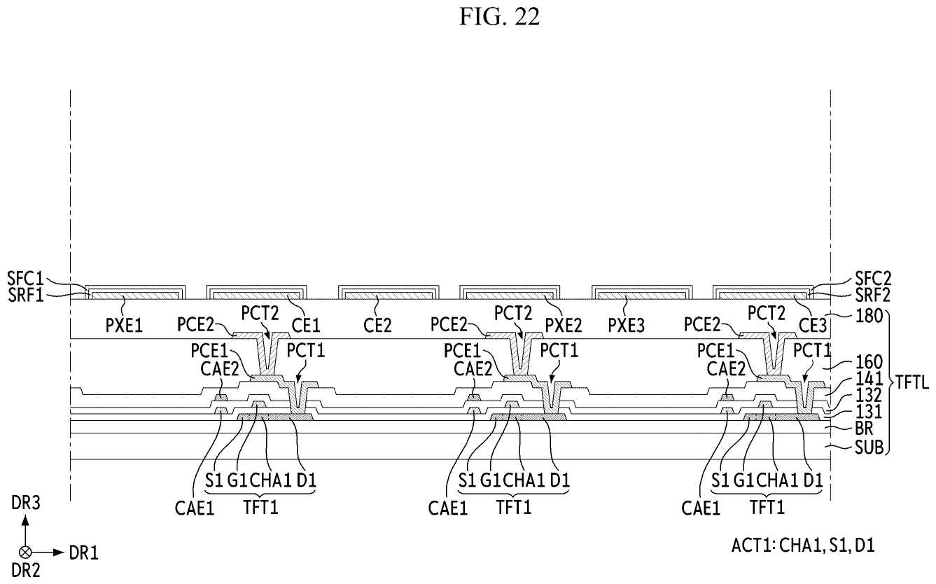

Thereafter, referring to FIG. 22, the sacrificial material layer SFCL and the reflective material layer SRFL may be patterned in the same process. For example, the mask pattern may be formed not to cover the sacrificial material layer SFCL that does not overlap the pixel electrodes PXE1, PXE2, and PXE3 and the common electrodes CE1, CE2, and CE3.

Wet-etch the sacrificial material layer SFCL that is not covered by the mask pattern, and wet-etch the reflective material layer SRFL exposed by the etching the sacrificial material layer SFCL by the same mask pattern without any additional photo process. The first chemical solution used during wet etching may react with both the sacrificial material layer SFCL and the reflective material layer SRFL.

As a result, the sacrificial material layer SFCL and the reflective material layer SRFL located between the pixel electrodes PXE1, PXE2, and PXE3 and the common electrodes CE1, CE2, and CE3 are etched, thereby forming the semiconductor substrate SSUB. Further, the reflective electrodes SRF1 and SRF2 and sacrificial electrodes SFC1 and SFC2 may be sequentially stacked on the pixel electrodes PXE1, PXE2, and PXE3 and the common electrodes CE1, CE2, and CE3. The mask pattern may be removed through an ashing process after forming reflective electrodes SRF1 and SRF2 and sacrificial electrodes SFC1 and SFC2 on it.

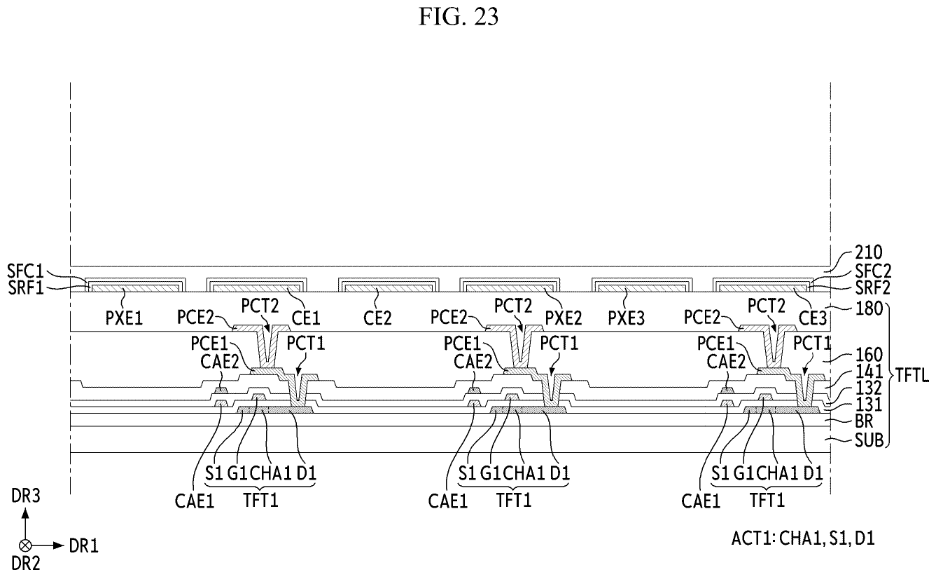

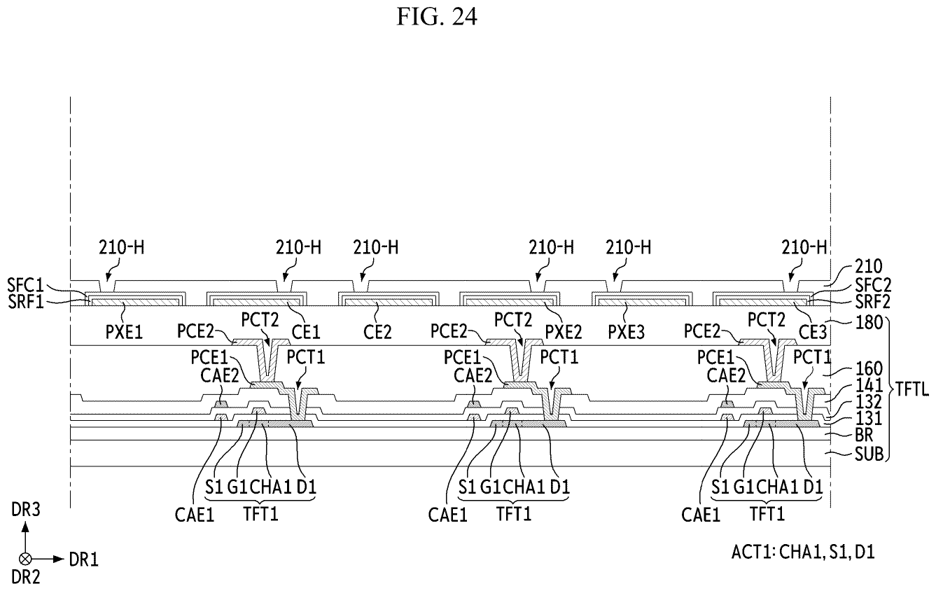

Referring to FIGS. 23 and 24, an organic layer 210 having a through hole 210-H is formed (S130 in FIG. 18).

Referring to FIG. 23, the organic layer 210 may be applied to the entire surface of the substrate SUB to cover the sacrificial electrodes SFC1 and SFC2, the pixel electrodes PXE1, PXE2, and PXE3, and the common electrodes CE1, CE2, and CE3.

When the organic layer 210 is a photosensitive organic film, such as photoresist, the organic layer 210 may be soft baked at the first temperature. Thereafter, the through hole 210-H is formed so that the organic layer 210 exposes a portion of the sacrificial electrodes SFC1 and SFC2.

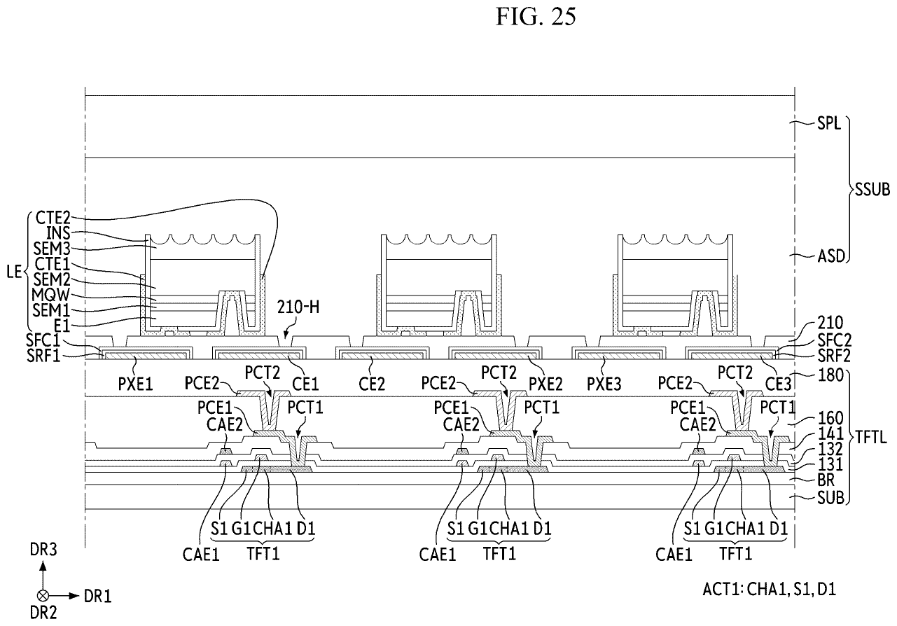

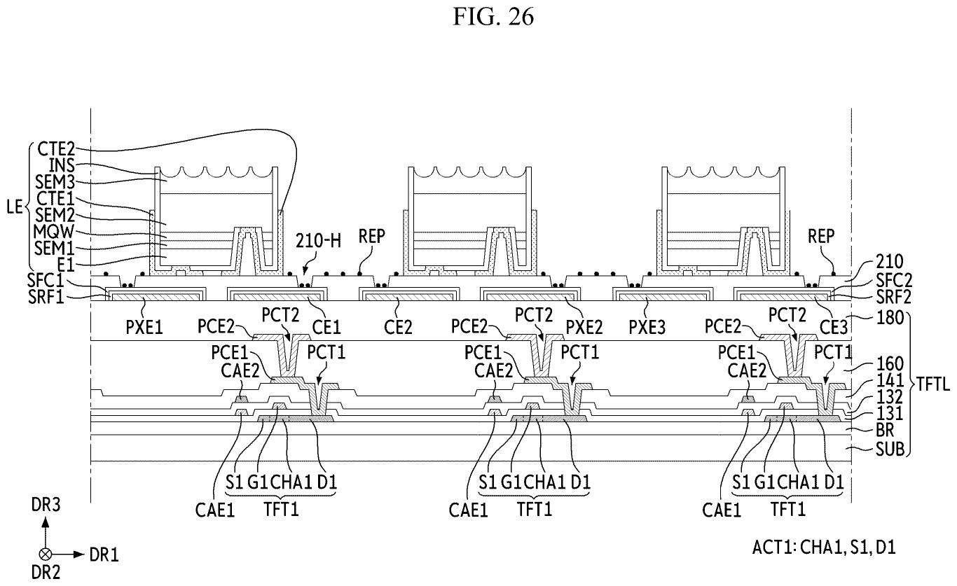

Referring to FIGS. 25 and 26, the light-emitting element LE on the first substrate SSUB is transferred to the organic layer 210, and the first substrate SSUB is removed (S140 in FIG. 18).

For example, referring to FIG. 25, the first substrate SSUB is placed on the substrate SUB so that the light-emitting element LE on the first substrate SSUB faces the organic layer 210. Thereafter, the light-emitting element LE is heat pressed on the organic layer 210. Accordingly, at least a portion of the light-emitting element LE may be embedded in the organic layer 210 and temporarily fixed thereto. When the fluidity of the organic layer 210 is low or the organic layer 210 is rigid, the depth at which the light-emitting element LE is inserted or embedded in the organic layer 210 may be relatively very small, or the light-emitting element LE may be placed on the organic layer 210 without being inserted or embedded in the organic layer 210. Then, the organic layer 210 may be completely cured at a second temperature that is higher than the first temperature. The first temperature may be approximately 100 degrees Celsius, and the second temperature may be approximately 230 degrees Celsius, but embodiments of the present disclosure are not limited thereto. Furthermore, the process of completely curing the organic layer 210 at the second temperature may be performed for approximately 30 minutes.

Furthermore, because the adhesive layer ASD has fluidity and elasticity, during heat pressing of the light-emitting elements LE, the light-emitting elements LE are embedded into the adhesive layer ASD, so that the adhesive material of the adhesive layer ASD not only fills the space between the light-emitting elements LE, but also contacts the organic layer 210 and the exposed sacrificial electrodes SFC1 and SFC2 through the through hole 210-H of the organic layer 210. On the other hand, the adhesive layer ASD is partially melted during heat pressing, leaving residual particles on the surface in contact with the adhesive layer ASD. The residual particles are a by-product of the process and are one of the contaminants. Therefore, the remaining particles may be referred to as contaminant particles.

Thereafter, the first substrate SSUB may be removed by separating it from the light-emitting element LE. For example, a laser is irradiated to a desired light-emitting element LE in consideration of the arrangement spacing between the plurality of light-emitting elements LE located on the first substrate SSUB. The adhesion of the adhesive layer attached to the laser-irradiated light-emitting element LE may decrease, causing the light-emitting element LE to be physically or naturally separated from the first substrate SSUB.

After the first substrate SSUB is separated, residual particles REP may adhere to the organic layer 210 to which the adhesive material is bonded and to the bottom surface of the through hole 210-H. If a connection electrode is formed on the top of the residual particle REP, conductivity problems may occur. For example, when the connection electrode is formed with residual particles REP generated on the bottom of the through hole 210-H with a small contact area, the contact resistance may increase, and the distribution of resistance may increase. Accordingly, dark spots may occur when the display panel is turned on, and the reliability of the display panel may be reduced.

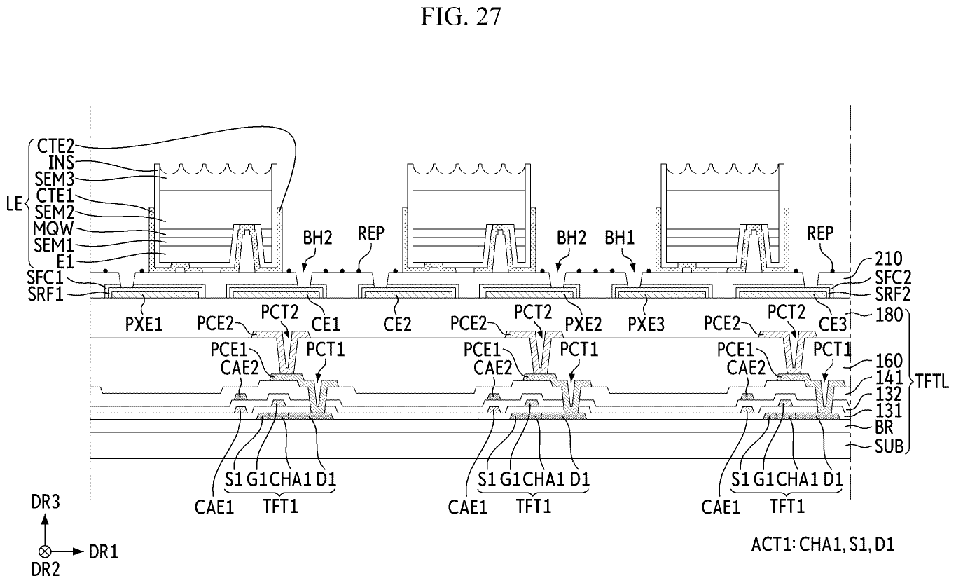

Referring to FIGS. 27 and 28, connection holes BH1 and BH2 are formed, and connection electrodes BE1 and BE2 are formed (S150 in FIG. 18).

A first sacrificial electrode SFC1 exposed by the through hole 210-H is etched to form a connection hole BH1 penetrating the first sacrificial electrode SFC1. Additionally, the second sacrificial electrode SFC2 exposed by the through hole 210-H is etched to form a connection hole BH2 penetrating the second sacrificial electrode SFC2. The connection hole BH1 and the connection hole BH2 may be formed by wet etching but are not limited thereto. The residual particles REP formed at the bottom of the through hole 210-H may be removed by etching the sacrificial electrodes SFC1 and SFC2.

At this time, the degree of etching of the sacrificial electrodes SFC1 and SFC2 may be adjusted by adjusting the etchant or etching time, and by etching only the top surface of the sacrificial electrodes SFC1 and SFC2, and by then stopping the etching, the sacrificial electrodes SFC1 and SFC2 may not be completely removed from the bottom of the connection hole BH1 and the connection hole BH2 as shown in FIG. 9. As such, even when only the upper portions of the sacrificial electrodes SFC1 and SFC2 are etched, no residual particles REP remain at the bottom of the connection holes BH1 and BH2.

Then, referring to FIG. 28, a first connection electrode BE1 for connecting the first contact electrode CTE1 and the pixel electrode PXE of the light-emitting element LE located on the organic layer 210 and a second connection electrode BE2 for connecting the second contact electrode CTE2 and the common electrode PXE are formed.

The first connection electrodes BE1 contact the bottom of the first connection hole BH1. As described with reference to FIG. 27, because no residual particles REP remain at the bottom of the first connection hole BH1, the first connection electrode BE1 may contact the first reflection electrode SRF1 without lifting.

In this way, the second connection electrodes BE2 contact the bottom of the second connection hole BH2. As described with reference to FIG. 27, because no residual particles REP remain at the bottom of the second connection hole BH2, the second connection electrode BE2 may contact the second reflection electrode SRF2 without bumping. As a result, the possibility of dark spots occurring in the display panel may be reduced, minimized, or prevented.

An organic film, a light-blocking layer, a wavelength conversion layer, a light transmission layer, and a color filter layer are sequentially formed (S160 in FIG. 18).

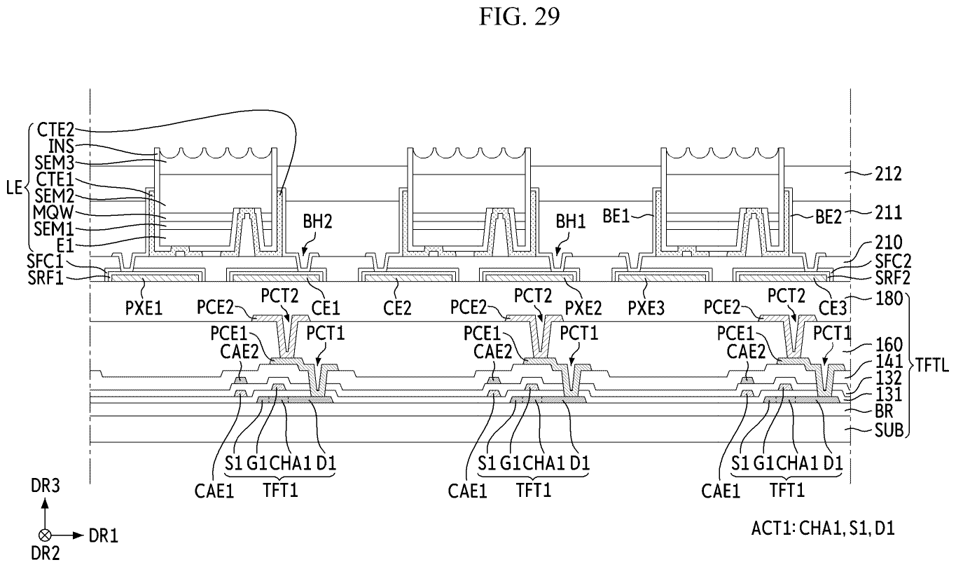

Referring to FIG. 29, a second organic film 211 and a third organic film 212 fix the light-emitting elements LE, and may flatten the steps caused by the light-emitting elements LE.

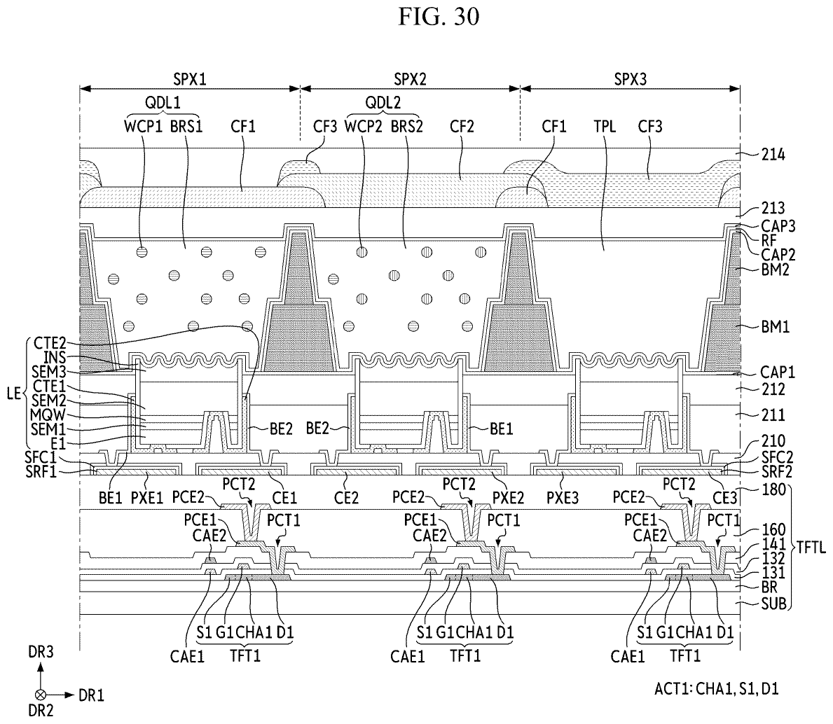

Then, as shown in FIG. 30, a first capping layer CPL1 is formed on the third organic film 212 and the light-emitting elements LE, and a first light-blocking layer BM1 and a second light-blocking layer BM2 are formed on the first capping layer CPL1 so as not to overlap with the light-emitting elements LE in the third direction DR3. Then, a second capping layer CPL2 covers the first light-blocking layer BM1, the second light-blocking layer BM2, and the first capping layer CPL1. Then, a reflective film RF covers the second capping layer CPL2 located on the first light-blocking layer BM1 and the second light-blocking layer BM2.

Then, a first light conversion layer QDL1 is formed on each of the first sub-pixels SPX1, a second light conversion layer QDL2 is formed on each of the second sub-pixels SPX2, and a light transmission layer TPL is formed on each of the third sub-pixels SPX3. Then, a third capping layer CPL3 covers the first light conversion layers QDL1, the second light conversion layers QDL2, and the light transmission layer TPL. Then, a fourth organic film 213 is formed on the third capping layer CPL3.

Then, a first color filter CF1 overlaps the first light conversion layers QDL1 in the third direction DR3, and a second color filter CF2 overlaps the second light conversion layers QDL2 in the third direction DR3, and a third color filter CF3 overlaps the light transmission layers TPL in the third direction DR3 on the fourth organic film 213. The first color filter CF1, the second color filter CF2, and the third color filter CF3 may all be formed in the area overlapping with the first light-blocking layer BM1 and the second light-blocking layer BM2 in the third direction DR3.

Then, a fifth organic film 214 is formed on the first color filter CF1, the second color filter CF2, and the third color filter CF3.

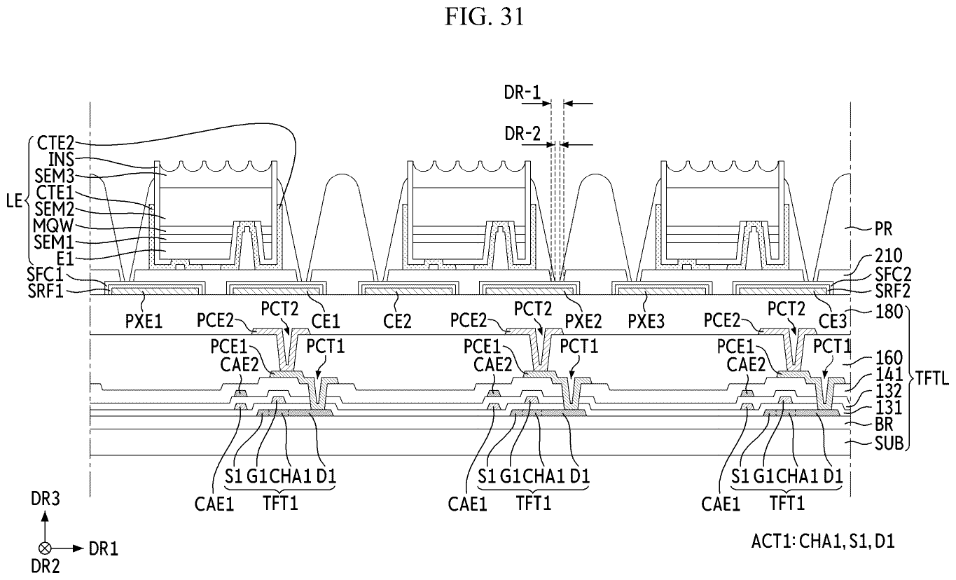

FIGS. 31 and 32 are diagrams to illustrate another method of operation 150 of FIG. 18.

Referring to FIGS. 31 and 32, the first connection hole BH1 and the second connection hole BH2 form a stepped structure of increasingly wider diameters in an upward direction, and the connection electrodes BE1 and BE2 may be formed, as described with reference to FIG. 8 (S150 in FIG. 18).

A photoresist opens the bottoms of the first connection hole BH1 and the second connection hole BH2, and may cover both the organic layer 210 and the side electrodes CTE1 and CTE2 of the light-emitting element LE. A portion of the bottom (the top of the sacrificial electrodes SFC1 and SFC2) of the first and second connection holes BH1 and BH2 is covered by the thickness of the photoresist covering the side surface of the organic layer 210. For example, the diameter of the bottom of the connection holes BH1 and BH2 (the top of the sacrificial electrodes SFC1 and SFC2) may be about 10 μm, and the diameter of the bottom exposed by the photoresist may be about 4.5 μm but is limited to this.

The bottom of the connection holes BH1 and BH2 (sacrificial electrodes SFC1 and SFC2) that are not covered by photoresist may be wet etched. The second chemical solution used during wet etching may react only to the sacrificial electrodes SFC1 and SFC2, and may not react to the reflective electrodes SRF1 and SRF2.

Accordingly, as shown in FIG. 32, the sacrificial electrodes SFC1 and SFC2 in the first connection hole BH1 and the second connection hole BH2 may be etched to expose the reflective electrodes SRF1 and SRF2. Thereafter, the photoresist is removed to partially expose the upper portion of the sacrificial electrodes SFC1 and SFC2 that was covered by the photoresist. The top of the exposed sacrificial electrodes SFC1, SFC2 may have residual particles REP on it.

Then, as described with reference to FIGS. 29 and 30, an organic film, a light-blocking layer, a wavelength conversion layer, a light transmission layer, and a color filter layer are sequentially formed (S160 in FIG. 18). The description described with reference to FIGS. 29 and 30 will not be repeated.

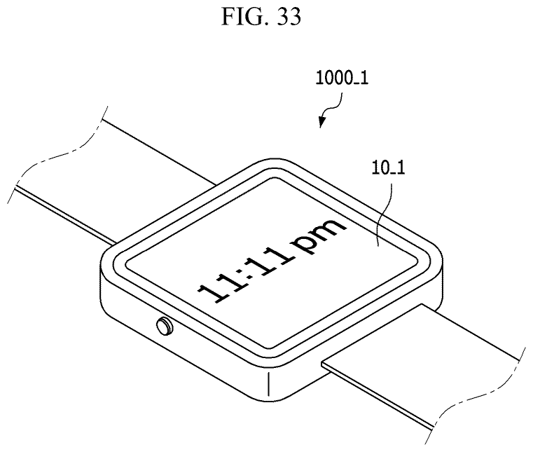

FIG. 33 is a view of a smart watch including a display device according to one or more embodiments.

Referring to FIG. 33, a display device 10_1 according to one or more embodiments may be applied to a smart watch 1000_1 which is one of smart devices.

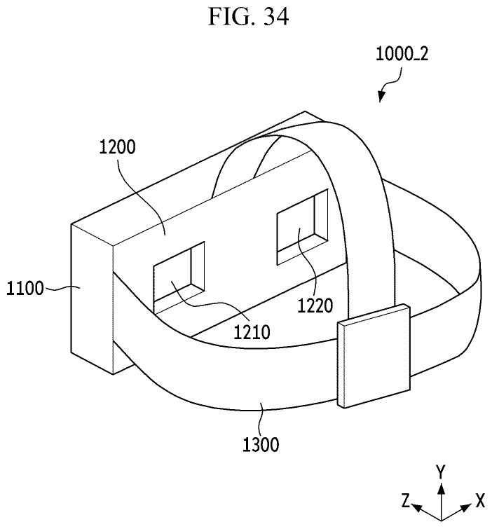

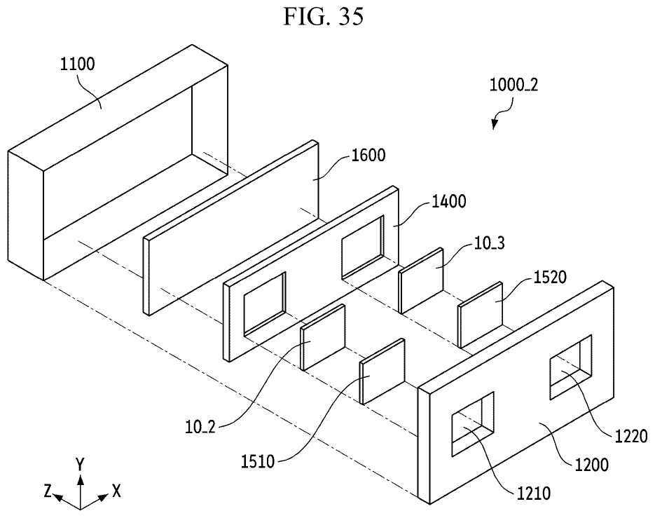

FIGS. 34 and 35 are views of a virtual reality (VR) device including a display device according to one or more embodiments.

Referring to FIGS. 34 and 35, a head-mounted display device 1000_2 according to one or more embodiments includes a first display device 10_2, a second display device 10_3, a display device housing 1100, a housing cover 1200, a first eyepiece 1210, a second eyepiece 1220, a head-mounted band 1300, a middle frame 1400, a first optical member 1510, a second optical member 1520, and a control circuit board 1600.

The first display device 10_2 provides an image to a user's left eye, and the second display device 10_3 provides an image to the user's right eye. Each of the first display device 10_2 and the second display device 10_3 is substantially the same as the display device 10 described with reference to FIGS. 1 and 2. Therefore, a description of the first display device 10_2 and the second display device 10_3 will be omitted.

The first optical member 1510 may be located between the first display device 10_2 and the first eyepiece 1210. The second optical member 1520 may be located between the second display device 10_3 and the second eyepiece 1220. Each of the first optical member 1510 and the second optical member 1520 may include at least one convex lens.

The middle frame 1400 may be located between the first display device 10_2 and the control circuit board 1600, and may be located between the second display device 10_3 and the control circuit board 1600. The middle frame 1400 supports and fixes the first display device 10_2, the second display device 10_3, and the control circuit board 1600.

The control circuit board 1600 may be located between the middle frame 1400 and the display device housing 1100. The control circuit board 1600 may be connected to the first display device 10_2 and the second display device 10_3 through a connector. The control circuit board 1600 may convert an image source received from the outside into digital video data DATA, and may transmit the digital video data DATA to the first display device 10_2 and the second display device 10_3 through the connector.

The control circuit board 1600 may transmit the digital video data DATA corresponding to a left image optimized for a user's left eye to the first display device 10_2, and may transmit the digital video data DATA corresponding to a right image optimized for the user's right eye to the second display device 10_3. Alternatively, the control circuit board 1600 may transmit the same digital video data DATA to the first display device 10_2 and the second display device 10_3.

The display device housing 1100 houses the first display device 10_2, the second display device 10_3, the middle frame 1400, the first optical member 1510, the second optical member 1520, and the control circuit board 1600. The housing cover 1200 is placed to cover an open surface of the display device housing 1100. The housing cover 1200 may include the first eyepiece 1210 on which a user's left eye is placed and the second eyepiece 1220 on which the user's right eye is placed. Although the first eyepiece 1210 and the second eyepiece 1220 are located separately in FIGS. 33 and 34, embodiments of the present specification are not limited thereto. The first eyepiece 1210 and the second eyepiece 1220 may also be combined into one.

The first eyepiece 1210 may be aligned with the first display device 10_2 and the first optical member 1510, and the second eyepiece 1220 may be aligned with the second display device 10_3 and the second optical member 1520. Therefore, a user can view an image of the first display device 10_2, which is enlarged as a virtual image by the first optical member 1510, through the first eyepiece 1210 and can view an image of the second display device 10_3, which is enlarged as a virtual image by the second optical member 1520, through the second eyepiece 1220.

The head-mounted band 1300 fixes the display device housing 1100 to a user's head so that the first eyepiece 1210 and the second eyepiece 1220 of the housing cover 1200 are kept placed on the user's left and right eyes, respectively. When the display device housing 1200 is implemented to be lightweight and small, the head-mounted display device 1000_2 may include an eyeglass frame as illustrated in FIG. 33 instead of the head-mounted band 1300.

In addition, the head-mounted display device 1000_2 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi® module, or a Bluetooth® module (Wi-Fi® being a registered trademark of the non-profit Wi-Fi Alliance, and Bluetooth® being a registered trademark of Bluetooth Sig, Inc., Kirkland, WA).

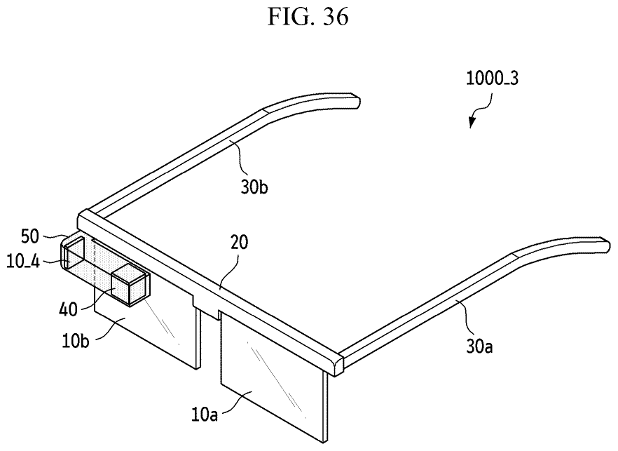

FIG. 36 is a view of a VR device including a display device according to one or more embodiments. FIG. 26 illustrates a VR device 1000_3 to which a display device 10_4 according to one or more embodiments has been applied.

Referring to FIG. 36, the VR device 1000_3 according to one or more embodiments may be a device in the form of glasses. The VR device 1000_3 may include the display device 10_4, a left lens 10a, a right lens 10b, a support frame 20, eyeglass frame legs 30a and 30b, a reflective member 40, and a display device housing 50.

In FIG. 36, a case where the VR device 1000_3 is a glasses-type display device including the eyeglass frame legs 30a and 30b is illustrated as an example. That is, the VR device 1000_3 is not limited to the one illustrated in FIG. 35 and can be applied in various forms to various other electronic devices.

The display device housing 50 may include the display device 10_4 and the reflective member 40. An image displayed on the display device 10_4 may be reflected by the reflective member 40 and provided to a user's right eye through the right lens 10b. Accordingly, the user may view a VR image displayed on the display device 10_4 through the right eye.

Although the display device housing 50 is located at a right end of the support frame 20 in FIG. 36, embodiments of the present specification are not limited thereto. For example, the display device housing 50 may also be located at a left end of the support frame 20. In this case, an image displayed on the display device 10_4 may be reflected by the reflective member 40 and provided to the user's left eye through the left lens 10a. Accordingly, the user may view a VR image displayed on the display device 10_4 through the left eye. Alternatively, the display device housing 50 may be located at both the right end and the left end of the support frame 20. In this case, the user may view a VR image displayed on the display device 10_4 through both the left eye and the right eye.

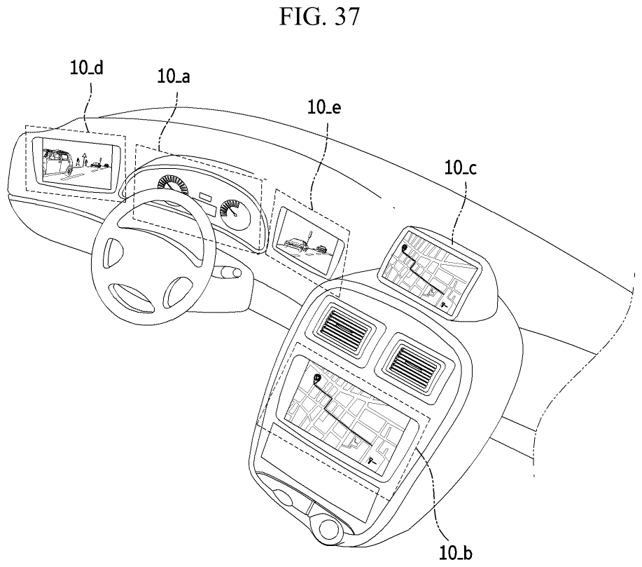

FIG. 37 is a view illustrating a vehicle instrument cluster and center fascia including display devices according to one or more embodiments. FIG. 37 illustrates a vehicle to which display devices 10_a through 10_e according to one or more embodiments have been applied.

Referring to FIG. 37, the display devices 10_a through 10_c may be applied to an instrument cluster of the vehicle, a center fascia of the vehicle, or a center information display (CID) located on a dashboard of the vehicle. In addition, the display devices 10_d and 10_e may be applied to room mirror displays that replace side mirrors of the vehicle.

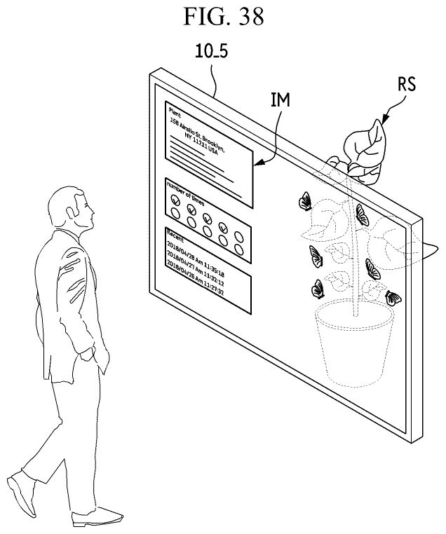

FIG. 38 is a view of a transparent display device including a display device according to one or more embodiments.

Referring to FIG. 38, a display device 10_5 according to one or more embodiments may be applied to a transparent display device. The transparent display device may transmit light while displaying an image IM. Therefore, a user located in front of the transparent display device cannot only view the image IM displayed on the display device 10_5, but also may view an object RS or the background located behind the transparent display device. When the display device 10_5 is applied to the transparent display device, a substrate of the display device 10_5 may include a light transmitting portion that can transmit light or may be made of a material that can transmit light.

In concluding the detailed description, those skilled in the art will appreciate that many variations and modifications can be made to the embodiments without substantially departing from the aspects of the disclosure. Therefore, the disclosed embodiments of the disclosure are used in a generic and descriptive sense only and not for purposes of limitation.

What is claimed is:

1. A display device comprising:
a substrate;
a pixel electrode and a common electrode above the substrate;
a first reflective electrode and a second reflective electrode respectively above the pixel electrode and the common electrode;
a first sacrificial electrode and a second sacrificial electrode respectively above the first reflective electrode and the second reflective electrode;
an organic layer above the first sacrificial electrode and the second sacrificial electrode;
a light-emitting element above the organic layer, and comprising a semiconductor stack, a first contact electrode, and a second contact electrode;
a first connection electrode connecting the pixel electrode and the first contact electrode through a first connection hole in the organic layer and the first sacrificial electrode; and
a second connection electrode connecting the common electrode and the second contact electrode through a second connection hole in the organic layer and the second sacrificial electrode.

2. The display device of claim 1, wherein the first connection hole penetrates the organic layer and the first sacrificial electrode to expose the first reflective electrode, and
wherein the second connection hole penetrates the organic layer and the second sacrificial electrode to expose the second reflective electrode.

3. The display device of claim 1, wherein the first connection hole is defined by a downwardly concave groove penetrating the organic layer above the first sacrificial electrode,
wherein the second connection hole is defined by a downwardly concave groove penetrating the organic layer above the second sacrificial electrode.

4. The display device of claim 1, wherein the first connection hole and the second connection hole have a stepped structure with a diameter that increases upwardly.

5. The display device of claim 4, wherein the first connection hole and the second connection hole have step portions respectively defined by one of the reflective electrodes, one of the sacrificial electrodes, and the organic layer.

6. The display device of claim 1, further comprising an element sacrificial electrode between the organic layer and the first contact electrode and the second contact electrode and completely overlapping one surface of the light-emitting element.

7. The display device of claim 1, wherein the light-emitting element further comprises,
a conductive layer between the organic layer and the semiconductor stack; and
a protective film on sides of the conductive layer and on sides of the semiconductor stack,
wherein the first contact electrode is on the protective film, and is connected to the conductive layer exposed through the protective film, and
wherein the second contact electrode is on the protective film, and is in a hole penetrating a portion of the conductive layer and the semiconductor stack.

8. The display device of claim 1, wherein the semiconductor stack further comprises:
a first semiconductor layer above the organic layer, and comprising a semiconductor material doped with a first conductivity type dopant;
an active layer above the first semiconductor layer; and
a second semiconductor layer above the active layer, and comprising a semiconductor material doped with a second conductivity type dopant,
wherein the first contact electrode is on a first side of the first semiconductor layer, on a first side of the active layer, and on a portion of the first side of the second semiconductor layer, and
wherein the second contact electrode is on a second side of the first semiconductor layer, on a second side of the active layer, and on a portion of the second side of the second semiconductor layer.

9. A display device comprising:
a substrate;
a pixel electrode and a common electrode above the substrate;
a first reflective electrode and a second reflective electrode respectively above the pixel electrode and the common electrode;
a first sacrificial electrode above the first reflective electrode, and exposing a portion of a top surface of the first reflective electrode;
a second sacrificial electrode above the second reflective electrode, and exposing a portion of a top surface of the second reflective electrode;
an organic layer above the first sacrificial electrode and the second sacrificial electrode;
a light-emitting element above the organic layer, and comprising a semiconductor stack, a first contact electrode, and a second contact electrode;
a first connection electrode connecting the pixel electrode and the first contact electrode, and connected to the portion of the top surface of the first reflective electrode; and
a second connection electrode connecting the common electrode and the second contact electrode, and connected to the portion of the top surface of the second reflective electrode.

10. A display device comprising:
a substrate;
a pixel electrode above the substrate;
a reflective electrode respectively above the pixel electrode;
a sacrificial electrode above the reflective electrode;
an organic layer above the sacrificial electrode; and
a light-emitting element above the organic layer and comprising a semiconductor stack and a contact electrode; and
a connection electrode connecting the pixel electrode and the contact electrode through a connection hole in the organic layer and the sacrificial electrode.

11. The display device of claim 10, wherein the connection hole penetrates the organic layer and the sacrificial electrode to expose the reflective electrode.

12. The display device of claim 10, wherein the connection hole is defined by a groove penetrating the organic layer, and concave in a downward direction above the sacrificial electrode.

13. The display device of claim 10, wherein the light-emitting element further comprises a protective film on a side of the semiconductor stack, and
wherein the contact electrode is on the protective film.

14. The display device of claim 10, wherein the semiconductor stack further comprises,
a first semiconductor layer above the organic layer, and comprising a semiconductor material doped with a first conductivity type dopant;
an active layer above the first semiconductor layer; and
a second semiconductor layer above the active layer, and comprising a semiconductor material doped with a second conductivity type dopant,
wherein the contact electrode is on an entire side surface of the first semiconductor layer, on an entire side surface of the active layer, and on a portion of a side surface of the second semiconductor layer.

15. A method of manufacturing a display device comprising:
preparing light-emitting elements comprising a semiconductor stack, a first contact electrode, and a second contact electrode;
forming a substrate on which a pixel electrode and a common electrode are arranged;
stacking a first reflective electrode and a first sacrificial electrode above the pixel electrode, and a second reflective electrode and a second sacrificial electrode above the common electrode;
forming an organic layer defining a through hole above the first sacrificial electrode and the second sacrificial electrode;
transferring the light-emitting elements onto the organic layer so that the first contact electrode and the second contact electrode respectively face the pixel electrode and the common electrode;
etching the first sacrificial electrode and the second sacrificial electrode exposed by the through hole to form a first connection hole and a second connection hole;
forming a first connection electrode connecting the pixel electrode and the first contact electrode through the first connection hole; and
forming a second connection electrode connecting the common electrode and the second contact electrode through the second connection hole.

16. The method of claim 15, wherein the stacking the first reflective electrode and the first sacrificial electrode above the pixel electrode, and the second reflective electrode and the second sacrificial electrode above the common electrode, comprises:
depositing a reflective material layer above a surface of the substrate to cover the pixel electrode and the common electrode;
depositing a sacrificial material layer above the surface of the substrate to cover the reflective material layer; and
partially etching the sacrificial material layer and the reflective material layer using a first chemical solution to which the first sacrificial electrode and the second sacrificial electrode react.

17. The method of claim 15, wherein the transferring the light-emitting elements onto the organic layer comprises:
arranging the light-emitting elements above the organic layer; and
transferring the light-emitting elements onto the organic layer by heat pressing the light-emitting elements,
wherein residual particles of an adhesive layer are on the organic layer, on the first sacrificial electrode, and on the second sacrificial electrode exposed by the through hole due to the heat pressing.

18. The method of claim 17, further comprising removing the residual particles from the first sacrificial electrode and the second sacrificial electrode when the first sacrificial electrode and the second sacrificial electrode are etched.

19. The method of claim 15, wherein, during the forming of the second connection electrode:
bottoms of the first connection hole and the second connection hole are open;
a photoresist covers a side of the organic layer; and
a stepped structure of connection holes with diameters increasing upwardly are formed by wet etching using the photoresist and a second chemical solution,
wherein the second chemical solution comprises a material that reacts with the first sacrificial electrode and the second sacrificial electrode, and that does not react with the first reflective electrode or the second reflective electrode.

20. The method of claim 19, wherein the first connection hole and the second connection hole have stepping portions respectively defined by the reflective electrode, the sacrificial electrode, and the organic layer,
wherein a portion of the stepping portions defined by the sacrificial electrode has residual particles generated during transfer of the light-emitting elements.

21. An electronic device comprising a display device comprising:
a substrate;
a pixel electrode and a common electrode above the substrate;
a first reflective electrode and a second reflective electrode respectively above the pixel electrode and the common electrode;
a first sacrificial electrode and a second sacrificial electrode respectively above the first reflective electrode and the second reflective electrode;
an organic layer above the first sacrificial electrode and the second sacrificial electrode;
a light-emitting element above the organic layer, and comprising a semiconductor stack, a first contact electrode, and a second contact electrode;
a first connection electrode connecting the pixel electrode and the first contact electrode through a first connection hole in the organic layer and the first sacrificial electrode; and
a second connection electrode connecting the common electrode and the second contact electrode through a second connection hole in the organic layer and the second sacrificial electrode.

22. The electronic device of claim 21, wherein the electronic device comprises a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).
